(19) United States
(12) Patent Application Publication
(10) Pub. No.: US 2026/0143809 A1
(43) Pub. Date: May 21, 2026

(54) SEMICONDUCTOR DEVICE

(71) Applicant: Samsung Electronics Co., Ltd., Suwon-si (KR)

(72) Inventors: Seongkwang Kim, Suwon-si (KR); Donghoon Hwang, Suwon-si (KR); Byungho Moon, Suwon-si (KR); Jaeho Jeon, Suwon-si (KR)

(21) Appl. No.: 19/203,371

(22) Filed: May 9, 2025

(30) Foreign Application Priority Data
Nov. 18, 2024 (KR) 10-2024-0164533

(51) Int. Cl. H10D 84/85; H10D 84/01

(52) U.S. Cl. CPC H10D 84/856; H10D 84/0167; H10D 84/017; H10D 84/0186; H10D 84/0188; H10D 84/851

(57) ABSTRACT

Disclosed is a semiconductor device including a substrate, a lower channel pattern on a surface of the substrate, an upper channel pattern on the lower channel pattern, a gate structure extending around the lower channel pattern and the upper channel pattern, lower source/drain patterns on sidewalls of the lower channel pattern, upper source/drain patterns on sidewalls of the upper channel pattern, a connection electrode electrically connecting a first upper source/drain pattern to a first lower source/drain pattern, and a protection pattern between the gate structure and the connection electrode, in which the protection pattern includes a first protection pattern and a second protection pattern on the first protection pattern and including an insulating material having a dielectric constant less than a dielectric constant of the first protection pattern.

### CROSS-REFERENCE TO RELATED APPLICATION

This application claims priority to and the benefit of Korean Patent Application No. 10-2024-0164533 filed in the Korean Intellectual Property Office on Nov. 18, 2024, the entire contents of which are incorporated herein by reference.

### BACKGROUND

The present disclosure relates to a semiconductor device.

A semiconductor is a material belonging to an intermediate region of conduction between a conductor and a nonconductor, and refers to a material that conducts electricity under certain conditions. Various semiconductor devices may be manufactured by using these semiconductor materials, and for example, memory devices and the like may be manufactured. Such semiconductor devices may be used in various electronic devices.

As the electronic industry progressively develops, demands on the properties of semiconductor devices are gradually increasing. For example, there is an increasing demand for high reliability, high speed, and/or multi-functionalization of semiconductor devices. In order to satisfy these required characteristics, structures within semiconductor devices are becoming increasingly complex and integrated.

### SUMMARY

The present disclosure attempts to provide a semiconductor device with improved electrical characteristics and a method of manufacturing the same.

The effects of the present disclosure are not limited to the foregoing effects, and other non-mentioned effects will be clearly understood by those skilled in the art from the description below.

Some embodiments of the present disclosure provides a semiconductor device including a substrate, a lower channel pattern on a surface of the substrate, an upper channel pattern on the lower channel pattern, a gate structure extending around the lower channel pattern and the upper channel pattern, lower source/drain patterns on sidewalls of the lower channel pattern, upper source/drain patterns on sidewalls of the upper channel pattern, a connection electrode electrically connecting a first upper source/drain pattern of the upper source/drain patterns to a first lower source/drain pattern of the lower source/drain patterns, and a protection pattern between the gate structure and the connection electrode, in which the protection pattern includes a first protection pattern and a second protection pattern on the first protection pattern and the second protection pattern includes a second insulating material having a second dielectric constant that is less than a first dielectric constant of a first insulating material of the first protection pattern.

Another some embodiments of the present disclosure provides a semiconductor device including: a substrate, a lower channel pattern on a surface of the substrate, an upper channel pattern above the lower channel pattern, a gate structure extending around the lower channel pattern and the upper channel pattern, lower source/drain patterns on sidewalls of the lower channel pattern, upper source/drain patterns on sidewalls of the upper channel pattern, a connection electrode electrically connecting a first upper source/drain pattern of the upper source/drain patterns to a first lower source/drain pattern of the lower source/drain patterns, and a protection pattern between a first portion of a side surface of the gate structure and the connection electrode, in which a first air gap is between the connection electrode and a second portion of the side surface of the gate structure.

Another some embodiments of the present disclosure provides a semiconductor device including a substrate, a lower channel pattern on a surface of the substrate, an upper channel pattern above the lower channel pattern, an intermediate insulation pattern between the upper channel pattern and the lower channel pattern, a gate structure extending around the lower channel pattern and the upper channel pattern, a gate spacer on a portion of a side surface of the gate structure, lower source/drain patterns on sidewalls of the lower channel pattern, upper source/drain patterns on sidewalls of the upper channel pattern, a connection electrode extending into a first upper source/drain pattern of the upper source/drain patterns in a first direction perpendicular to the surface of the substrate and having an end portion electrically connected to a first lower source/drain pattern of the lower source/drain patterns, an upper contact electrode on an upper surface of a second source/drain pattern of the upper source/drain patterns that is adjacent to the first source/drain pattern, the connection electrode extends into the first upper source/drain pattern, and a protection pattern between the gate spacer and the connection electrode and between the gate spacer and the upper contact electrode, in which the protection pattern includes a first protection pattern and a second protection pattern on the first protection pattern and including an insulating material having a dielectric constant that is less than a dielectric constant of the first protection pattern.

The semiconductor device according to some embodiments may include the protection pattern between the gate structure and the connection electrode, and at least a portion of the protection pattern may include a low-k dielectric material. The semiconductor device according to the embodiments may include an air gap between two source/drain patterns disposed upward and downward.

According to some embodiments, parasitic capacitance inside the semiconductor device may be reduced, and thus electrical characteristics of the semiconductor device may be improved.

### BRIEF DESCRIPTION OF THE DRAWINGS

FIG. 1 is a top plan view illustrating a semiconductor device according to some embodiments.

FIG. 2 is a cross-sectional view of the semiconductor device taken along line I1-I1′ of FIG. 1.

FIG. 3 is an enlarged cross-sectional view of a region ‘A’ of FIG. 2.

FIG. 4 is a cross-sectional view of the semiconductor device taken along line I2-I2′ of FIG. 1.

FIG. 5 is a cross-sectional view of the semiconductor device taken along line I3-I3′ of FIG. 1.

FIG. 6 is a cross-sectional view of the semiconductor device taken along line I4-I4′ of FIG. 1.

FIG. 7 is a cross-sectional view of the semiconductor device taken along line I1-I1′ of FIG. 1.

FIG. 8 is an enlarged cross-sectional view of a region ‘A’ of FIG. 7.

FIG. 9 is a cross-sectional view of the semiconductor device taken along line I1-I1′ of FIG. 1.

FIG. 10 is an enlarged cross-sectional view of a region ‘A’ of FIG. 9.

FIG. 11 is a cross-sectional view of the semiconductor device taken along line I1-I1′ of FIG. 1.

FIG. 12 is a cross-sectional view of the semiconductor device taken along line I2-I2′ of FIG. 1.

FIG. 13 is an enlarged cross-sectional view of a region ‘B’ of FIG. 11.

FIGS. 14 to 49 are process cross-sectional views illustrating a method of manufacturing a semiconductor device according to some embodiments.

### DETAILED DESCRIPTION

In the following detailed description, only certain embodiments of the present disclosure have been illustrated and described, simply by way of illustration. The present disclosure may be variously implemented and is not limited to the following embodiments.

The drawings and description are to be regarded as illustrative in nature and not restrictive. Like reference numerals designate like elements throughout the specification.

In addition, the size and thickness of each configuration illustrated in the drawings are arbitrarily illustrated for understanding and ease of description, but the present disclosure is not limited thereto. In the drawings, the thickness of layers, films, panels, regions, etc., are exaggerated for clarity. In the drawings, for understanding and ease of description, the thickness of some layers and regions is exaggerated.

It will be understood that when an element such as a layer, film, region, or substrate is referred to as being “on” another element, it may be directly on the other element or intervening elements may also be present. In contrast, when an element is referred to as being “directly on” another element, there are no intervening elements present. Further, it will be understood that when an element such as a layer, film, region, or substrate is referred to as being “on” another element, it may be directly on the other element or intervening elements may also be present.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

Also, throughout the specification, two directions parallel to and intersecting an upper surface of a substrate are defined as a first direction D1 and a second direction D2, respectively, and a direction perpendicular to the upper surface of the substrate is defined as a third direction D3. In one example, the first direction D1 and the second direction D2 may be orthogonal to and/or intersect each other each other.

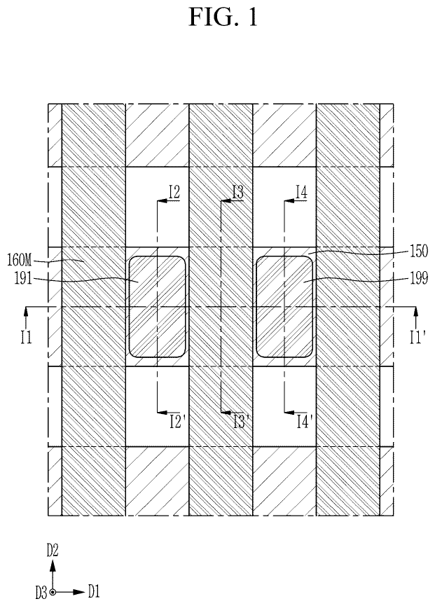

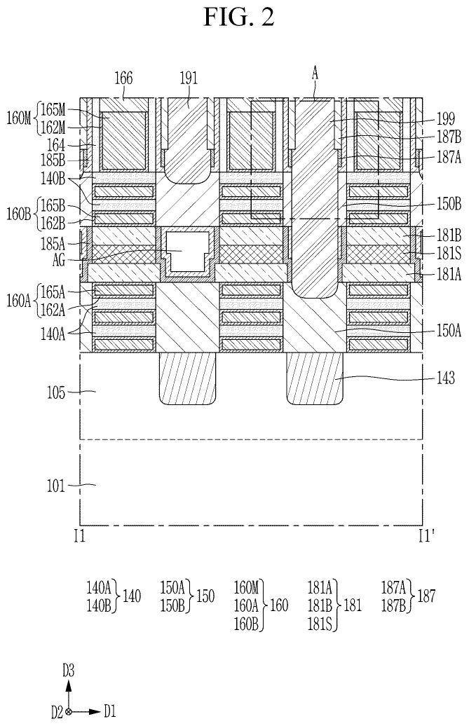

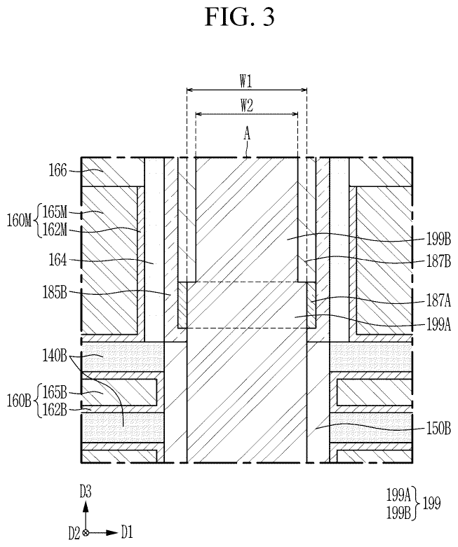

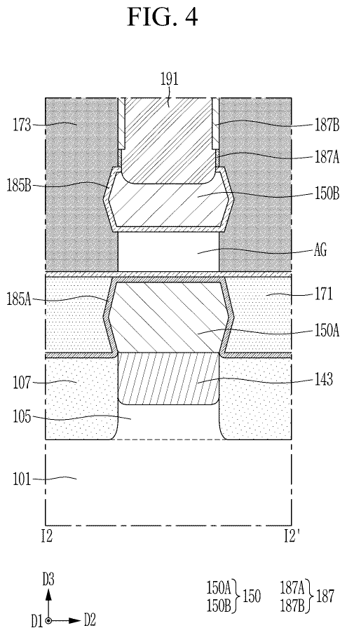

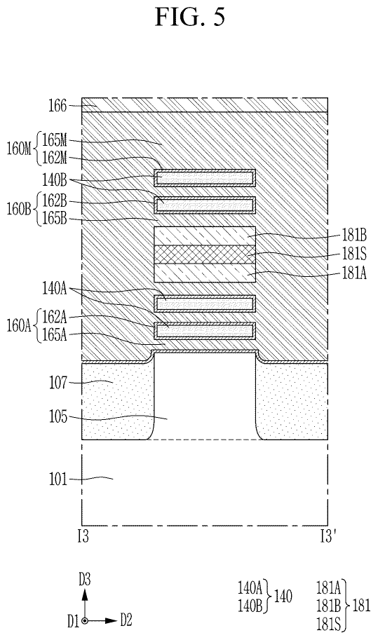

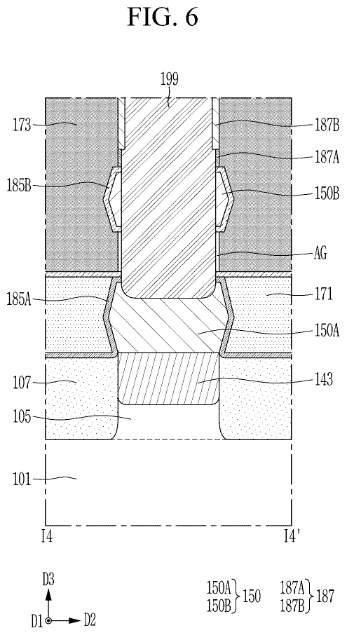

Hereinafter, a semiconductor device according to some embodiments will be described with reference to FIGS. 1 to 6. Specifically, FIG. 1 is a top plan view illustrating a semiconductor device according to some embodiments, FIG. 2 is a cross-sectional view taken along line I1-I1′ of FIG. 1, FIG. 3 is an enlarged cross-sectional view of a region ‘A’ of FIG. 2, FIG. 4 is a cross-sectional view of the semiconductor device taken along line I2-I2′ of FIG. 1, FIG. 5 is a cross-sectional view of the semiconductor device taken along line I3-I3′ of FIG. 1, and FIG. 6 is a cross-sectional view of the semiconductor device taken along line I4-I4′ of FIG. 1.

Referring to FIGS. 1 to 6, a semiconductor device according to some embodiments may include a substrate 101, a lower channel pattern 140A positioned on the substrate 101, an upper channel pattern 140B positioned on the lower channel pattern 140A, a gate structure 160 surrounding or extending around the lower channel pattern 140A and the upper channel pattern 140B, lower source/drain patterns 150A positioned on opposite sides of the lower channel pattern 140A, upper source/drain patterns 150B positioned on opposite sides of the upper channel pattern 140B, a connection electrode 199 connecting the upper source/drain pattern 150B and the lower source/drain pattern 150A, and a protection pattern 187 positioned between the gate structure 160 and the connection electrode 199.

The substrate 101 may be silicon-on-insulator (SOI) or bulk silicon. In some embodiments, the substrate 101 may be a silicon substrate or may include other materials, such as, silicon germanium (SiGe), silicon germanium on insulator (SGOI), indium antimonide, lead telluride compound, indium arsenide, indium phosphide, gallium arsenide, or gallium antimonide, but is not limited thereto.

The substrate 101 may include an upper surface and a lower surface. The upper surface and the lower surface of the substrate 101 may be formed as planes parallel to the first direction D1 and the second direction D2 intersecting the first direction D1. The upper surface of the substrate 101 may be a surface that is opposite to the lower surface of the substrate 101 in the third direction D3. The upper surface of the substrate 101 may be referred to as a front side. The lower surface of the substrate 101 may be referred to as a back side.

The semiconductor device according to the embodiments may further include an active pattern 105 disposed on the substrate 101. The active pattern 105 may be grown from the substrate 101 by an epitaxial growth method, or may be formed by etching a partial region of the substrate 101. In the embodiments, the active pattern 105 may include silicon (Si) or germanium (Ge), which is an element semiconductor material. In some embodiments, the active pattern 105 may include a compound semiconductor. A side surface of the active pattern 105 may be covered or overlapped by a field insulation layer 107 to be described below.

The active pattern 105 may protrude from the upper surface of the substrate 101 in the third direction D3. The active pattern 105 may extend in the first direction D1. Referring to FIGS. 2, 4, and 6, the active pattern 105 may be positioned below the source/drain pattern 150. The active pattern 105 may overlap the source/drain pattern 150 in the third direction D3. The active pattern 105 may also be positioned under the gate structure 160 and/or the channel pattern 140. The active pattern 105 may overlap the gate structure 160 and/or the channel pattern 140 in the third direction D3. A height at which the active pattern 105 protrudes in the third direction D3 may vary according to a position. For example, a height of the active pattern 105 overlapping the source/drain pattern 150 in the third direction D3 may be lower than a height of the active pattern 105 overlapping the gate structure 160 and/or the channel pattern 140 in the third direction D3. However, the present disclosure is not limited thereto, and the active pattern 105 may have a constant height.

A semiconductor device according to the embodiments may include at least one transistor structure. For example, the semiconductor device according to the embodiments may include a first transistor structure including a plurality of lower channel patterns 140A and a second transistor structure including a plurality of upper channel patterns 140B. The first and second transistor structures according to the embodiments may be formed in a Gate All Around Field Effect Transistor (GAAFET) structure, such as a Multi-Bridge Channel Field Effect Transistor (MBCFET™), in which the plurality of lower channel patterns 140A and the plurality of upper channel patterns 140B are surrounded by the gate structure 160 in plan view. In the other words, the gate structure 160 may extend around the plurality of upper channel patterns 140B.

The first and second transistor structures according to the embodiments may be formed in a three dimensional stacked FET (3DSFET) structure stacked in the third direction D3. In this case, the first transistor structure may be any one of an N-type MOSFET and a P-type MOSFET, and the second transistor structure may be the other of a P-type MOSFET and an N-type MOSFET. In the embodiments, the first and second transistor structures may be an N-type MOSFET and a P-type MOSFET, respectively, but are not limited thereto. Hereinafter, a case where the plurality of lower channel patterns 140A and the plurality of upper channel patterns 140B are stacked in the third direction D3 to form a 3D-SFET structure will be described. However, the present disclosure is not limited to this case.

The plurality of channel patterns 140 may be positioned on the substrate 101. In the embodiments, the plurality of channel patterns 140 may include the plurality of lower channel patterns 140A positioned on the substrate 101 and the plurality of upper channel patterns 140B positioned on the plurality of lower channel patterns 140A.

The plurality of lower channel patterns 140A may be positioned on the upper surface of the substrate 101. The plurality of lower channel patterns 140A may be spaced apart from each other in the third direction D3. Here, the third direction D3 may be a direction intersecting the first direction D1 and the second direction D2. For example, the third direction D3 may be a thickness direction of the substrate 101.

In the embodiments, as illustrated in FIG. 5, widths of the plurality of lower channel patterns 140A in the second direction D2 may be substantially the same. In some embodiments, widths of the plurality of lower channel patterns 140A in the second direction D2 may decrease as the distance from the upper surface of the substrate 101 increases. As illustrated in FIG. 2, widths of the plurality of lower channel patterns 140A in the first direction D1 may be substantially the same. In some embodiments, widths of the plurality of lower channel patterns 140A in the first direction D1 may decrease as the distance from the upper surface of the substrate 101 increases.

The plurality of upper channel patterns 140B may be positioned on the plurality of lower channel patterns 140A. Specifically, a plurality of upper channel patterns 140B may be positioned to be spaced apart from a plurality of lower channel patterns 140A in the third direction D3. For example, as illustrated in FIGS. 2 and 5, an intermediate insulation pattern 181 to be described later may be positioned on the plurality of lower channel patterns 140A, and the plurality of upper channel patterns 140B may be positioned on the intermediate insulation pattern 181. The upper channel patterns 140B may be positioned to be spaced apart from the plurality of lower channel patterns 140A in the third direction D3 by the intermediate insulation pattern 181. The plurality of upper channel patterns 140B may be positioned to be spaced apart from each other in the third direction D3.

In the embodiments, as illustrated in FIG. 5, widths of the plurality of upper channel patterns 140B in the second direction D2 may be substantially the same. In some embodiments, widths of the plurality of upper channel patterns 140B in the second direction D2 may decrease as the distance from the upper surface of the substrate 101 increases. As illustrated in FIG. 2, widths of the plurality of upper channel patterns 140B in the first direction D1 may be substantially the same. In some embodiments, widths of the plurality of upper channel patterns 140B in the first direction D1 may decrease as the distance from the upper surface of the substrate 101 increases.

The plurality of lower channel patterns 140A and the plurality of upper channel patterns 140B may be multichannel active patterns. In the embodiments, the plurality of lower channel patterns 140A and the plurality of upper channel patterns 140B may have a nanosheet shape and may be semiconductor patterns including a semiconductor material.

The plurality of lower channel patterns 140A and the plurality of upper channel patterns 140B may be formed by etching a portion of the substrate 101, or may include an epitaxial layer grown from the substrate 101. The plurality of lower channel patterns 140A and the plurality of upper channel patterns 140B may include an elemental semiconductor material, such as silicon (Si) or germanium (Ge). Additionally, the plurality of lower channel patterns 140A and the plurality of upper channel patterns 140B may include compound semiconductors, for example, group IV-IV compound semiconductors or group III-V compound semiconductors.

The group IV-IV compound semiconductor may be, for example, a binary compound or a ternary compound including at least two of carbon (C), silicon (Si), germanium (Ge), and/or tin (Sn).

A group III-V compound semiconductor may be, for example, a binary compound, ternary compound, or tetrameric compound formed by combining at least one of the group III elements of aluminum (Al), gallium (Ga), and indium (In) with one of the group V elements of phosphorus (P), arsenic (As), and/or antimony (Sb).

In the embodiments, the plurality of channel patterns 140 may include silicon (Si). As another example, the plurality of channel patterns 140 may include silicon germanium (SiGe).

In FIGS. 2 and/or 5, two lower channel patterns 140A and two upper channel patterns 140B are illustrated as being stacked spaced apart along the third direction D3, but this is only for convenience of description and the present disclosure is not limited thereto. For example, the three or more lower channel patterns 140A and/or the three or more upper channel patterns 140B may be stacked while being spaced apart along the third direction D3. In some embodiments, one lower channel pattern 140A and/or one upper channel pattern 140B may be stacked while being spaced apart along the third direction D3.

The semiconductor device according to the embodiments may further include the intermediate insulation pattern 181. The intermediate insulation pattern 181 may be positioned on the plurality of lower channel patterns 140A. The intermediate insulation pattern 181 may be positioned between the lower channel pattern 140A which is positioned at the uppermost portion and the upper channel pattern 140B which is positioned at the lowermost portion. Also, the intermediate insulation pattern 181 may be positioned between a lower gate structure 160A which is positioned at the uppermost portion and an upper gate structure 160B which is positioned at the lowermost portion.

The intermediate insulation pattern 181 may include a plurality of layers. Referring to FIGS. 2 and 5, the intermediate insulation pattern 181 may include a first intermediate insulation pattern 181A, a second intermediate insulation pattern 181B positioned on the first intermediate insulation pattern 181A, and a third intermediate insulation pattern 181S positioned between the first intermediate insulation pattern 181A and the second intermediate insulation pattern 181B.

In the embodiments, the width of the second intermediate insulation pattern 181B and the width of the third intermediate insulation pattern 181S in the first direction D1 may be substantially the same. In the embodiments, the width of the first intermediate insulation pattern 181A in the first direction D1 may be greater than the width of the second intermediate insulation pattern 181B and the width of the third intermediate insulation pattern 181S in the first direction D1. However, the present disclosure is not limited thereto, and the first intermediate insulation pattern 181A, the second intermediate insulation pattern 181B, and the third intermediate insulation pattern 181S may have substantially the same width in the first direction D1.

The intermediate insulation pattern 181 may include various insulation materials. For example, the intermediate insulation pattern 181 may include silicon oxide, silicon nitride, silicon nitric oxide, or a combination thereof. The intermediate insulation pattern 181 may separate a plurality of lower channel patterns 140A and a plurality of upper channel patterns 140B from each other.

In the embodiments, the first intermediate insulation pattern 181A and the second intermediate insulation pattern 181B may include the same insulating material, and the third intermediate insulation pattern 181S may include an insulating material different from the remaining two intermediate insulation patterns 181A and 181B. However, the present disclosure is not limited thereto, and the first intermediate insulation pattern 181A, the second intermediate insulation pattern 181B, and the third intermediate insulation pattern 181S may also include the same insulating material. In this case, a boundary between the third intermediate insulation pattern 181S and the first intermediate insulation pattern 181S and a boundary between the third intermediate insulation pattern 181A and the second intermediate insulation pattern 181B may not be visually recognized.

Unlike the illustration in FIGS. 2 and 5, the intermediate insulation pattern 181 may be formed as a single layer. Even in this case, the plurality of upper channel patterns 140B and the plurality of lower channel patterns 140A may be spaced apart from each other by the intermediate insulation pattern 181.

The semiconductor device according to the embodiments may further include a field insulation layer 107 positioned on the substrate 101. The field insulation layer 107 may cover or overlap at least a portion of the side surface of the active pattern 105. For example, as illustrated in FIG. 4 to FIG. 6, the field insulation layer 107 may cover or overlap at least a portion of the side surface of the active pattern 105. A portion of the side surface of the active pattern 105 may be covered or overlapped by the field insulation layer 107, and the remaining portion of the side surface of the active pattern 105 may be covered or overlapped by the gate structure 160. Although FIG. 5 illustrates that the field insulation layer 107 covers or overlaps a portion of the side surface of the active pattern 105 and the remaining portion is covered or overlapped by the gate structure 160, the present disclosure is not limited thereto. For example, the field insulation layer 107 may cover or overlap the entire side surface of the active pattern 105. The field insulation layer 107 may overlap the active pattern 105 in the second direction D2. The field insulation layer 107 may not be positioned on the upper surface of the active pattern 105.

The field insulation layer 107 may include, for example, a film of an oxide, nitride, a nitric oxide, or a combination thereof. The field insulation layer 107 is illustrated as a single film, but is illustrated for illustrative purposes only, and the present disclosure is not limited thereto.

The gate structure 160 may be positioned on the active pattern 105. The gate structure 160 may extend in the second direction D2. The gate structure 160 may be spaced apart from each other in the first direction D1. The gate structure 160 may be positioned on the active pattern 105. The gate structure 160 may intersect the active pattern 105. The gate structure 160 may surround each of a plurality of channel patterns 140.

In the embodiments, the first and second transistor structures may be configured to share one gate structure 160. Specifically, the first transistor structure may include the plurality of lower channel patterns 140A, the gate structure 160 surrounding the plurality of lower channel patterns 140A, and the lower source/drain pattern 150A connected to the plurality of lower channel patterns 140A at one side of the gate structure 160. The second transistor structure may include the plurality of upper channel patterns 140B, the gate structure 160 surrounding or extending around the plurality of upper channel patterns 140B, and the upper source/drain pattern 150B connected to the plurality of upper channel patterns 140B at one side of the gate structure 160. In this case, as illustrated in FIG. 5, one gate structure 160 surrounds or extends around the plurality of lower channel patterns 140A and the plurality of upper channel patterns 140B, so that the first and second transistor structures may share one gate structure 160.

The gate structure 160 may include the lower gate structure 160A, the upper gate structure 160B, and a main gate structure 160M. The lower gate structure 160A may be positioned between the plurality of lower channel patterns 140A adjacent to each other in the third direction D3, between the substrate 101 and the lower channel pattern 140A positioned at the lowermost portion, and between the lower channel pattern 140A and the intermediate insulation pattern 181 positioned at the uppermost portion. The upper gate structure 160B may be positioned between the plurality of upper channel patterns 140B adjacent to each other in the third direction D3, and between the upper channel pattern 140B positioned at the lowermost portion and the intermediate insulation pattern 181. The main gate structure 160M may be positioned on the upper channel pattern 140B positioned at the uppermost portion.

The lower gate structure 160A may be adjacent to the lower source/drain pattern 150A, which will be described later. The upper gate structure 160B may be adjacent to the upper source/drain pattern 150B, which will be described later. The main gate structure 160M may be positioned on the lower gate structure 160A, the upper gate structure 160B, and the plurality of upper channel patterns 140B.

According to the embodiments, the lower gate structures 160A and the upper gate structures 160B may be alternately stacked with the plurality of channel patterns 140. Referring to FIGS. 2 and 5, the lower gate structures 160A and the plurality of lower channel patterns 140A may be alternately stacked. Although FIG. 2 and FIG. 5 illustrate that three lower gate structures 160A and two lower channel patterns 140A are alternately stacked, the number of lower gate structures 160A and the number of lower channel patterns 140A that are alternately stacked are not limited. Referring to FIGS. 2 and 5, the upper gate structures 160B and the plurality of upper channel patterns 140B may be alternately stacked. Although FIG. 2 and FIG. 5 illustrate that two upper gate structures 160B and two upper channel patterns 140B are alternately stacked, the number of upper gate structures 160B and the number of upper channel patterns 140B that are alternately stacked are not limited.

Each of the lower gate structure 160A and the upper gate structure 160B may include gate electrodes 165A and 165B and gate insulation films 162A and 162B.

The gate electrodes 165A and 165B may be positioned on the active pattern 105. For example, the lower gate electrode 165A may be positioned on the active pattern 105, and the upper gate electrode 165B may be positioned on the lower gate electrode 165A. The gate electrodes 165A and 165B may intersect the active pattern 105. For example, the active pattern 105 may extend in the first direction D1, and the gate electrodes 165A and 165B may extend in the second direction D2. The gate electrodes 165A and 165B may surround or extends around the plurality of channel patterns 140 in plan view. For example, the lower gate electrode 165A may surround or extend around the plurality of lower channel patterns 140A, and the upper gate electrode 165B may surround or extend around the plurality of upper channel patterns 140B in plan view.

Additionally, at least some of the gate electrodes 165A and 165B may be positioned between the plurality of channel patterns 140. For example, the lower gate electrode 165A may be positioned between the plurality of lower channel patterns 140A, and the upper gate electrode 165B may be positioned between the plurality of upper channel patterns 140b.

The gate electrodes 165A and 165B may include a conductive material. The gate electrodes 165A and 165B may include at least one of a metal, a metal alloy, a conductive metal nitride, a metal silicide, a doped semiconductor material, a conductive metal oxide, and/or a conductive metal nitric oxide. The gate electrodes 165A and 165B may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonated nitride (TiAlC—N), titanium aluminum carbide (TiAlC), titanium carbide (TiC), tantalum carbonated nitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium mitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or combinations thereof, but are not limited thereto. The conductive metal oxide and the conductive metal nitric oxide may include an oxidized form of the above material, but are not limited thereto. The gate electrodes 165A and 165B may include the same material, but are not limited thereto, and the gate electrodes 165A and 165B may also include different materials.

The gate insulation films 162A and 162B may be positioned along the perimeter of the plurality of channel patterns 140. For example, the lower gate insulation film 162A may be positioned along the circumference of each of the plurality of lower channel patterns 140A, and the upper gate insulation film 162B may be positioned along the circumference of each of the plurality of upper channel patterns 140B. The lower gate insulation film 162A may be positioned along the upper surface of the active pattern 105 overlapping the gate structure 160 in the third direction D3.

The lower gate insulation film 162A may be in direct contact with the active pattern 105, the plurality of lower channel patterns 140A, and the intermediate insulation pattern 181A. The upper gate insulation film 162B may be in direct contact with the plurality of upper channel patterns 140B and the second intermediate insulation pattern 181B. The gate insulation films 162A and 162B may be interposed between the plurality of channel patterns 140 and the gate electrodes 165A and 165B. The gate insulation films 162A and 162B may include a variety of insulating materials.

In the embodiments, the gate insulation films 162A and 162B are illustrated as a single film, but are not limited thereto. For example, the gate insulation films 162A and 162B may be multiple films including silicon oxide (SiO₂) and a high dielectric constant material. In this case, the high dielectric constant material may include a material having a higher dielectric constant than silicon oxide (SiO₂), such as hafnium oxide (HfO), aluminum oxide (Al₂O₃), or tantalum oxide (TaO).

The main gate structure 160M may be positioned on the upper gate structure 160B and the plurality of upper channel patterns 140B. The main gate structure 160M may be positioned on the upper surface of the upper channel pattern 140B positioned at the uppermost portion among the plurality of upper channel patterns 140B.

The main gate structure 160M may include a main gate electrode 165M and a main gate insulation film 162M.

The main gate electrode 165M may be positioned on the upper gate structure 160B and the plurality of upper channel patterns 140B. The main gate electrode 165M may be positioned on the upper surface of the upper channel pattern 140B positioned at the uppermost portion among the plurality of upper channel patterns 140B. Accordingly, four sides of the plurality of channel patterns 140 may be surrounded by the gate electrodes 165A and 165B and the main gate electrode 165M in cross-sectional view. The main gate electrode 165M may include the same conductive material as the gate electrodes 165A and 165B. For example, the main gate electrode 165M may include at least one of a metal, a metal alloy, a conductive metal nitride, a metal silicide, a doped semiconductor material, a conductive metal oxide, and/or a conductive metal nitric oxide.

The main gate insulation film 162M may extend along a side of the main gate electrode 165M. The main gate insulation film 162M may extend along a side of a gate spacer 164 to be described below. The main gate insulation film 162M may include a variety of insulating materials.

In the embodiments, the main gate insulation film 162M is illustrated as a single film, but is not limited thereto. For example, the main gate insulation film 162M may be made of multiple layers including silicon oxide (SiO₂) and a high dielectric constant material. In this case, the high dielectric constant material may include a material having a higher dielectric constant than silicon oxide (SiO₂), such as hafnium oxide (HfO), aluminum oxide (AlO), or tantalum oxide (TaO).

The semiconductor device according to the embodiments may further include a gate spacer 164 and a capping layer 166.

The capping layer 166 may be positioned on the main gate structure 160M. The upper surface of the capping layer 166 may be placed on the same plane as the upper surface of the upper contact electrode 191, which will be described later. Opposite side surfaces of the capping layer 166 may be in contact with the gate spacer 164. Unlike the illustration, the capping layer 166 may cover or overlap the upper surface of the gate spacer 164.

The capping layer 166 may include, for example, at least one of silicon nitride (SiN), silicon nitric oxide (SiON), silicon carbonated nitride (SiCN), silicon carbonated nitride (SiOCN), and/or combinations thereof. The capping layer 166 may include a material having an etch selectivity with respect to the second interlayer insulation layer 173 which is to be descried below.

The gate spacer 164 may be positioned on the side of the main gate electrode 165M. In the embodiments, the gate spacer 164 may also be positioned on the side surface of the capping layer 166. The gate spacer 164 may not be positioned on the side surfaces of the lower gate electrode 165A and the upper gate electrode 165B. The gate spacer 164 may not be positioned on the side surface of each of the lower channel patterns 140A and the upper channel patterns 140B. The gate spacer 164 may not be disposed between the active pattern 105 and the channel patterns 140A and 140B. The gate spacer 164 may not be disposed between the plurality of channel patterns 140A and 140B adjacent to each other in the third direction D3. Although the gate spacer 164 is illustrated as being a single layer, it is only for convenience of description and the present disclosure is not limited thereto.

The gate spacer 164 may include, for example, at least one of silicon nitride (SiN), silicon nitric oxide (SiON), silicon oxide (SiO₂), silicon carbonated nitride (SiOCN), silicon boron nitride (SiBN), silicon boron oxide nitride (SiOBN), silicon carbonated oxide (SiOC) and/or combinations thereof. Although the gate spacer 164 is illustrated as being a single layer, it is only for convenience of description and the present disclosure is not limited thereto.

The source/drain patterns 150 may be positioned on at least one side of the gate structure 160. For example, the source/drain patterns 150 may be positioned on opposite sides of the gate structure 160. For example, each of the source/drain patterns 150 may be positioned between two gate structures 160 arranged to be spaced apart from each other in the first direction D1. The source/drain patterns 150 may be positioned on the active pattern 105. The source/drain patterns 150 may be in contact with side surfaces of a plurality of channel patterns 140. The source/drain patterns 150 may be connected to the plurality of channel patterns 140. The source/drain patterns 150 according to the embodiments may include a lower source/drain pattern 150A and an upper source/drain pattern 150B.

The lower source/drain patterns 150A may be positioned on the active pattern 105. A lower surface of each of the lower source/drain patterns 150A may be in contact with the upper surface of the active pattern 105. The lower source/drain pattern 150A may be positioned on at least one side of the lower gate structure 160A. For example, the lower source/drain pattern 150A may be positioned on opposite sides of the lower gate structure 160A. For example, each of the lower source/drain patterns 150A may be positioned between two lower gate structures 160A arranged to be spaced apart from each other in the first direction D1. The lower source/drain patterns 150A may be connected with the plurality of lower channel patterns 140A.

The lower source/drain pattern 150A may be epitaxial patterns formed by a selective epitaxial growth process using a partial region of the active pattern 105 and the plurality of lower channel patterns 140A as seeds. The lower source/drain pattern 150A may serve as a source/drain for a first transistor structure utilizing the plurality of lower channel patterns 140A as channel regions.

The lower source/drain pattern 150A may include a semiconductor material. The lower source/drain pattern 150A may include, for example, silicon (Si) or germanium (Ge). In addition, the lower source/drain pattern 150A may include, for example, a binary compound or a ternary compound including at least two or more of carbon (C), silicon (Si), germanium (Ge), and/or tin (Sn). For example, the lower source/drain pattern 150A may include silicon (Si), silicon-germanium (SiGe), germanium (Ge), silicon carbide (SiC), and the like, but is not limited thereto. In the embodiments, the lower source/drain pattern 150A is illustrated as a single layer, but is not limited thereto, and the lower source/drain pattern 150A may be formed of two or more layers. For example, the lower source/drain pattern 150A may include a first layer conformally positioned in a recess region defined by side surfaces of the lower channel patterns 140A and the lower gate structures 160A and the upper surface of the active pattern 105, and a second layer filling a recess region above the first layer. In this case, a concentration of silicon (Si) or germanium (Ge) included in the first layer and the second layer may be different from each other. For example, a concentration of germanium (Ge) included in the first layer may be greater than a concentration of germanium (Ge) included in the second layer.

In the embodiments, the lower source/drain pattern 150A may be doped with impurities. For example, when the first transistor structure is a P-type MOSFET, the lower source/drain pattern 150A may include P-type impurities. For example, the lower source/drain pattern 150A may include boron (B), aluminum (Al), gallium (Ga), or a combination thereof.

The semiconductor device according to the embodiments may further include a dummy semiconductor pattern 143 positioned under the lower source/drain pattern 150A. The dummy semiconductor pattern 143 may be configured to connect the lower source/drain pattern 150A to wires. For example, when the semiconductor device according to the embodiments includes wires positioned under the substrate 101, at least a portion of the dummy semiconductor pattern 143 may be positioned between the lower source/drain pattern 150A and the wire under the substrate 101 to connect the lower source/drain pattern 150A and the wire under the substrate 101. Unlike the illustration in FIG. 2, the dummy semiconductor pattern 143 may not be positioned under some of the lower source/drain patterns 150A.

Referring to FIG. 4, the dummy semiconductor pattern 143 may extend inside the active pattern 105 in a direction toward the upper surface of the substrate 101. The lower surface of the dummy semiconductor pattern 143 may be positioned between the lower surface of the lower source/drain pattern 150A and the upper surface of the substrate 101. The upper surface of the dummy semiconductor pattern 143 may be in contact with the lower surface of the lower source/drain pattern 150A. Referring to FIGS. 2 and 4, the side surface of the dummy semiconductor pattern 143 may be covered with or overlap the active pattern 105 and the field insulation layer 107.

The dummy semiconductor pattern 143 may include a semiconductor material. In the embodiments, the dummy semiconductor pattern 143 may include the same material as the lower source/drain pattern 150A. For example, the dummy semiconductor pattern 143 may include silicon germanium (SiGe). In this case, a concentration of germanium (Ge) of the dummy semiconductor pattern 143 may be different from a concentration of germanium (Ge) of the lower source/drain pattern 150A. For example, a concentration of germanium (Ge) of the dummy semiconductor pattern 143 may be higher than a concentration of germanium (Ge) of the lower source/drain pattern 150A.

The semiconductor device according to the embodiments may further include a lower etch stop film 185A positioned on the lower source/drain pattern 150A. The lower etch stop film 185A may be positioned between the lower source/drain pattern 150A and the upper source/drain pattern 150B to be described later.

The lower etch stop film 185A may cover or overlap the lower source/drain pattern 150A. The lower etch stop film 185A may be positioned on at least a portion of the upper surface and the side surface of the lower source/drain pattern 150A. For example, referring to FIGS. 4 and 6, the lower etch stop film 185A may be positioned on two side surfaces facing the first interlayer insulation layer 171 to be described later along the second direction D2 among the entire side surface region of the lower source/drain pattern 150A. For example, referring to FIG. 2, the lower etch stop film 185A may not be positioned on two side surfaces facing the lower gate structure 160A and the lower channel pattern 140A along the first direction D1 among the entire side surface region of the lower source/drain pattern 150A.

The lower etch stop film 185A may also be positioned on the field insulation layer 107. In other words, the lower etch stop film 185A may be conformally positioned along the upper surface and the side surface of the lower source/drain pattern 150A and the upper surface of the field insulation layer 107.

The lower etch stop film 185A may also be positioned on a side surface of the intermediate insulation pattern 181. The lower etch stop film 185A may cover or overlap a side surface of the intermediate insulation pattern 181. Referring to FIG. 2, the lower etch stop film 185A may be conformally positioned inside a region defined by respective side surfaces of two adjacent intermediate insulation patterns 181 facing each other and the upper surface of the lower source/drain pattern 150A.

The upper surface of the lower etch stop film 185A may be positioned on the same plane as the upper surface of the intermediate insulation pattern 181. The upper surface of the lower etch stop film 185A may be in contact with a partial region of the lower surface of the upper source/drain pattern 150B, which will be described later. The lower etch stop film 185A may not be positioned on the upper surface of the intermediate insulation pattern 181.

Unlike the illustration in FIG. 2, the lower etch stop film 185A may cover or overlap only a partial region of the side surface of the intermediate insulation pattern 181. For example, the lower etch stop film 185A may cover or overlap only the side surface of one or two of the first intermediate insulation pattern 181A, the second intermediate insulation pattern 181B, and the third intermediate insulation pattern 181S. For example, the lower etch stop film 185A may cover or overlap only at least a partial region of the side surface of the first intermediate insulation pattern 181A and the side surface of the third intermediate insulation pattern 181S. For example, the lower etch stop film 185A may cover or overlap only at least a partial region of the side surface of the first intermediate insulation pattern 181A.

Unlike the illustration in FIG. 1 to FIG. 6, the lower etch stop film 185A may be omitted. In this case, the side surface of the lower source/drain pattern 150A may be covered or overlapped by a first interlayer insulation layer 171 to be described later.

The lower etch stop film 185A may include an insulating material. The lower etch stop film 185A may include, for example, at least one of silicon nitride (SiN), silicon nitric oxide (SiON), silicon oxide (SiO₂), silicon carbonated nitride (SiOCN), silicon boron nitride (SiBN), silicon boron oxide nitride (SiOBN), silicon carbonated oxide (SiOC) and/or combinations thereof. The lower etch stop film 185A is illustrated as a single film, but is only for convenience of description and the present disclosure is not limited thereto.

The semiconductor device according to the embodiments may further include the first interlayer insulation layer 171 positioned on the field insulation layer 107 and on the side surface of the lower source/drain pattern 150A. In the embodiments, the lower etch stop film 185A may be interposed between the first interlayer insulation layer 171 and the field insulation layer 107.

The first interlayer insulation layer 171 may be positioned on the lower etch stop film 185A. In the embodiments, the first interlayer insulation layer 171 may be positioned on the side surface of the lower source/drain pattern 150A. The first interlayer insulation layer 171 may cover or overlap the side surface of the lower source/drain pattern 150A. The first interlayer insulation layer 171 may be positioned on the field insulation layer 107.

In the embodiments, the first interlayer insulation layer 171 may not be positioned on the upper surface of the lower source/drain pattern 150A. The first interlayer insulation layer 171 may not overlap the intermediate insulation pattern 181 in a horizontal direction (e.g., the first direction D1). Referring to FIG. 2, the first interlayer insulation layer 171 may not be positioned between two facing side surfaces of two adjacent intermediate insulation patterns 181.

The first interlayer insulation layer 171 may have a flat upper surface. The upper surface of the first interlayer insulation layer 171 may be positioned on the same plane as the upper surface of the lower etch stop film 185A covering or overlapping the upper surface of the lower source/drain pattern 150A.

The first interlayer insulation layer 171 may include an insulating material. The first interlayer insulation layer 171 may include, for example, at least one of silicon nitride (SiN), silicon nitric oxide (SiON), silicon oxide (SiO₂), silicon carbonated nitride (SiOCN), silicon boron nitride (SiBN), silicon boron oxide nitride (SiOBN), silicon carbonated oxide (SiOC) and/or combinations thereof. Although it is illustrated that the first interlayer insulation layer 171 is a single film for convenience of description only, this is only for convenience of description and the present disclosure is not limited thereto.

The upper source/drain pattern 150B of the semiconductor device according to the embodiments may be positioned on the lower source/drain pattern 150A. The upper source/drain pattern 150B may be positioned to be spaced apart from the lower source/drain pattern 150A in the third direction D3. Referring to FIGS. 2, 4, and 6, the upper source/drain pattern 150B and the lower source/drain pattern 150A may be spaced apart from each other in the third direction D3 by the first interlayer insulation layer 171 and the lower etch stop film 185A. In the embodiments, an air gap AG, which will be described later, may be positioned between the lower source/drain pattern 150A and the upper source/drain pattern 150B.

The upper source/drain pattern 150B may be positioned on at least one side of the upper gate structure 160B. For example, the upper source/drain pattern 150B may be positioned on opposite sides of the upper gate structure 160B. For example, each of the upper source/drain patterns 150B may be positioned between two upper gate structures 160B arranged to be spaced apart from each other in the first direction D1. The upper source/drain pattern 150B may be connected to the plurality of upper channel patterns 140B. The upper source/drain pattern 150B may be in contact with side surfaces of the plurality of upper channel patterns 140B.

The upper source/drain pattern 150B may be epitaxial patterns formed by a selective epitaxial growth process using the plurality of upper channel patterns 140B as seeds. In this case, the upper source/drain pattern 150B may be a pattern formed by using opposite side surfaces of the plurality of upper channel patterns 140B as seeds.

The upper source/drain pattern 150B may serve as a source/drain of a second transistor structure using the plurality of upper channel patterns 140B as a channel region.

In the embodiments, as illustrated in FIG. 2, the upper surface of the upper source/drain pattern 150B may be positioned at substantially the same level as the upper surface of the upper channel pattern 140B positioned at the uppermost portion. In the embodiments, the lower surface of the upper source/drain pattern 150B may be positioned at a higher or lower level than the lower surface of the upper gate structure 160B positioned at the lowermost portion. That is, the upper surface of the upper source/drain pattern 150B may have substantially the same distance from the upper surface of the upper channel pattern 140B positioned at the uppermost portion and the upper surface of the substrate 101. Furthermore, the lower surface of the upper source/drain pattern 150B may be positioned at substantially the same level as the upper surface of the first interlayer insulation layer 171. The lower surface of the upper source/drain pattern 150B may be positioned at substantially the same level as the lower surface of the upper gate structure 160B positioned at the lowermost portion. However, the present disclosure is not limited thereto, and the upper surface of the upper source/drain pattern 150B may be positioned at a higher or lower level than the upper surface of the upper channel pattern 140B positioned at the uppermost portion.

The upper source/drain pattern 150B may include a semiconductor material. The upper source/drain pattern 150B may include the same material as the lower source/drain pattern 150A. The upper source/drain pattern 150B may include, for example, silicon (Si) or germanium (Ge). In addition, the upper source/drain pattern 150B may include, for example, a binary compound or a ternary compound including at least two or more of carbon (C), silicon (Si), germanium (Ge), and/or tin (Sn). For example, the upper source/drain pattern 150B may include silicon (Si), silicon-germanium (SiGe), germanium (Ge), silicon carbide (SiC), and/or the like, but is not limited thereto. In the embodiments, the upper source/drain pattern 150B is illustrated as a single layer, but is not limited thereto, and the upper source/drain pattern 150B may be formed of two or more layers. When the upper source/drain pattern 150B includes two or more layers, the concentration of silicon (Si) or germanium (Ge) included in each layer may be different from each other.

In the embodiments, the upper source/drain pattern 150B may be doped with impurities. For example, when the second transistor structure is an N-type MOSFET, the upper source/drain pattern 150B may include N-type impurities. For example, the upper source/drain pattern 150B may include phosphorus (P), antimony (Sb), arsenic (As), or a combination thereof.

In the semiconductor device according to the embodiments, an air gap AG may be positioned between the lower source/drain pattern 150A and the upper source/drain pattern 150B. The air gap AG may refer to an empty space positioned between one layer and the other layer. For example, the air gap AG may include air or gas used in a process of manufacturing the semiconductor device. The lower source/drain pattern 150A and the upper source/drain pattern 150B may be positioned to be spaced apart from each other in the third direction D3 with the air gap AG interposed therebetween.

The air gap AG may be positioned between two adjacent intermediate insulation patterns 181. Referring to FIG. 2, two adjacent intermediate insulation patterns 181 may be positioned to be spaced apart from each other along the first direction D1, with an air gap AG interposed therebetween. Specifically, the air gap AG may be positioned between two facing side surfaces of two adjacent intermediate insulation patterns 181 along the first direction D1. In the embodiments, the lower etch stop film 185A and an upper etch stop film 185B, which will be described later, may be interposed between the intermediate insulation pattern 181 and the air gap AG.

Referring to FIGS. 4 and 6, the upper etch stop film 185B, which will be described later, may be interposed between the air gap AG and the upper source/drain pattern 150B. The lower etch stop film 185A and the upper etch stop film 185B may be interposed between the air gap AG and the lower source/drain pattern 150A.

In the embodiments, the air gap AG may have a dielectric constant of a lower size (i.e., less than) compared to a dielectric constant of an insulating material included in insulation layers positioned around the surrounding region and the insulation patterns. For example, the air gap AG may have a lower dielectric constant compared to the interlayer insulation layers 171 and 173, the etch stop films 185A and 185B, and the field insulation layer 107. For example, the air gap AG may be filled with air, and the dielectric constant of air may be about 1. Since the semiconductor device according to the embodiments includes the air gap AG, internal parasitic capacitance may be reduced, and thus electrical characteristics of the semiconductor device may be improved.

The semiconductor device according to the embodiments may further include the upper etch stop film 185B positioned on the lower source/drain pattern 150A.

The upper etch stop film 185B may cover the upper source/drain pattern 150B. In the embodiments, the upper etch stop film 185B may surround four surfaces of the upper source/drain pattern 150B. Specifically, the upper etch stop film 185B may surround or extend around the upper surface, the lower surface, and two side surfaces facing along the second direction D2 of the upper source/drain pattern 150B, in cross-sectional view. The upper etch stop film 185B may not be positioned on two side surfaces facing the upper gate structure 160B and the upper channel pattern 140B along the first direction D1 among the entire side surface regions of the upper source/drain pattern 150B. In other words, the upper etch stop film 185B may be conformally positioned along at least a portion of the upper surface and a portion of the side surface and the lower surface of the upper source/drain pattern 150B.

The upper etch stop film 185B may be positioned between the lower surface of the upper source/drain pattern 150B and the air gap AG. The upper etch stop film 185B may be positioned between the side surface of the upper source/drain pattern 150B and a second interlayer insulation layer 173 to be described later. The upper etch stop film 185B may be positioned between the upper surface of the upper source/drain pattern 150B and the second interlayer insulation layer 173.

In the embodiments, a partial region of the upper etch stop film 185B may be penetrated by the upper contact electrode 191 or the connection electrode 199 to be described later. In other words, the upper contact electrode 191 or the connection electrode 199 may extend into the upper etch stop film 185B. Specifically, a partial region of the upper etch stop film 185B positioned on the upper surface of the upper source/drain pattern 150B may be penetrated by the upper contact electrode 191 or the connection electrode 199. In other words, the upper contact electrode 191 or the connection electrode 199 may extend into the upper source/drain pattern 150B.

The upper etch stop film 185B may also be positioned on the side surface of the gate spacer 164. Referring to FIG. 2, the upper etch stop film 185B may be positioned between the gate spacer 164 and an upper contact electrode 191 or the connection electrode 199 to be described later. The upper surface of the upper etch stop film 185B may be positioned on the same plane as the upper surfaces of the gate spacer 164 and the capping layer 166. The upper etch stop film 185B may not be positioned on the upper surfaces of the gate spacer 164 and the capping layer 166.

In the embodiments, the upper etch stop film 185B may be conformally positioned on the upper surface of the upper source/drain pattern 150B and the side surface of the gate spacer 164.

The upper etch stop film 185B may also be positioned on the side surface of the intermediate insulation pattern 181. Specifically, the upper etch stop film 185B may be positioned on the side surface of the lower etch stop film 185A covering the side surface of the intermediate insulation pattern 181. The upper etch stop film 185B may also be positioned on the upper surface of the lower source/drain pattern 150A. Specifically, the lower etch stop film 185A may be positioned on the upper surface of the lower etch stop film 185A covering or overlapping the upper surface of the lower source/drain pattern 150A. The upper etch stop film 185B may be conformally formed inside a region defined by an upper surface of a region covering or overlapping the upper surface of the lower source/drain pattern 150A among the entire region of the lower etch stop film 185A, a side surface of a region covering or overlapping the side surface of the intermediate insulation pattern 181, and the lower surface of the upper source/drain pattern 150B.

The upper etch stop film 185B may also be positioned on the first interlayer insulation layer 171. Referring to FIGS. 2 and 4, the upper etch stop film 185B may cover or overlap the upper surface of the first interlayer insulation layer 171 in a region overlapping the field insulation layer 107 in the third direction D3. The upper etch stop film 185B may be interposed between the second interlayer insulation layer 173 and the first interlayer insulation layer 171 to be described later in the region overlapping the first interlayer insulation layer 171 in the third direction D3. The upper etch stop film 185B may be interposed between the lower source/drain pattern 150A and the air gap AG or between the lower etch stop film 185A and the air gap AG in a region overlapping the lower source/drain pattern 150A in the third direction D3.

Unlike the illustration in FIG. 1 to FIG. 6, the upper etch stop film 185B may be omitted. In this case, the upper surface and the side surface of the upper source/drain pattern 150B may be in contact with the second interlayer insulation layer 173.

The upper etch stop film 185B may include an insulating material. In the embodiments, the upper etch stop film 185B may include the same insulating material as the lower etch stop film 185A. However, the present disclosure is not limited thereto, and the upper etch stop film 185B may include an insulating material different from that of the lower etch stop film 185A. The upper etch stop film 185B may include, for example, at least one of silicon nitride (SiN), silicon nitric oxide (SiON), silicon oxide (SiO₂), silicon carbonated nitride (SiOCN), silicon boron nitride (SiBN), silicon boron oxide nitride (SiOBN), silicon carbonated oxide (SiOC) and/or combinations thereof. The upper etch stop film 185B is illustrated as a single film, but is only for convenience of description and the present disclosure is not limited thereto.

The semiconductor device according to the embodiments may further include the second interlayer insulation layer 173 positioned on the first interlayer insulation layer 171. The second interlayer insulation layer 173 may cover or overlap the upper source/drain pattern 150B together with the upper etch stop film 185B. The second interlayer insulation layer 173 may be positioned on the upper etch stop film 185B. The second interlayer insulation layer 173 may be positioned on a partial region of the upper surface and on the side surface of the upper source/drain pattern 150B. The second interlayer insulation layer 173 may cover or overlap a side surface of the upper etch stop film 185B positioned on the side surface of the upper source/drain pattern 150B. Although not clearly illustrated, the second interlayer insulation layer 173 may be positioned between two main gate structures 160M adjacent to each other along the first direction D1. The second interlayer insulation layer 173 may also be positioned on the first interlayer insulation layer 171. The second interlayer insulation layer 173 may cover or overlap at least a portion of the upper surface of the upper etch stop film 185B overlapping the first interlayer insulation layer 171 in the third direction D3.

In the embodiments, the second interlayer insulation layer 173 may not overlap the lower source/drain pattern 150A and the upper source/drain pattern 150B in the third direction D3, or may overlap only in a partial region. Referring to FIGS. 2 and 4, in the embodiments, the air gap AG may be positioned between the upper surface of the lower source/drain pattern 150A and the lower surface of the upper source/drain pattern 150B, and the second interlayer insulation layer 173 may not be positioned in the region where the air gap AG is positioned. Between the upper surface of the source/drain pattern 150A and the lower surface of the upper source/drain pattern 150B, the second interlayer insulation layer 173 may be positioned at opposite sides of the region where the air gap AG is positioned. Referring to FIGS. 2 and 4, in the embodiments, the second interlayer insulation layer 173 positioned at opposite sides of the region where the air gap AG is positioned may include a part of a region overlapping the lower source/drain pattern 150A and the upper source/drain pattern 150B in the third direction D3.

Although not clearly illustrated, at least a portion of the second interlayer insulation layer 173 may overlap the main gate structure 160M in the first direction D1. The second interlayer insulation layer 173 may have an upper surface having a flat shape. The upper surface of the second interlayer insulation layer 173 may be positioned on the same plane as the upper surfaces of the gate spacer 164 and the capping layer 166. The second interlayer insulation layer 173 may not be positioned on the upper surfaces of the gate spacer 164 and the capping layer 166.

The second interlayer insulation layer 173 may include an insulating material. The second interlayer insulation layer 173 may include the same insulating material as the first interlayer insulation layer 171. However, the present disclosure is not limited thereto, and the second interlayer insulation layer 173 may include an insulating material different from that of the first interlayer insulation layer 171. The second interlayer insulation layer 173 may include, for example, at least one of silicon nitride (SiN), silicon nitric oxide (SiON), silicon oxide (SiO₂), silicon carbonated nitride (SiOCN), silicon boron nitride (SiBN), silicon boron oxide nitride (SiOBN), silicon carbonated oxide (SiOC) and/or combinations thereof. Although it is illustrated that the second interlayer insulation layer 173 is a single layer for convenience of description only, this is only for convenience of description and the present disclosure is not limited thereto.

The connection electrode 199 may connect the lower source/drain pattern 150A and the upper source/drain pattern 150B. Specifically, the connection electrode 199 may electrically connect the lower source/drain pattern 150A and the upper source/drain pattern 150B, which are positioned to be spaced apart from each other in the third direction D3.

The connection electrode 199 may be positioned between the lower source/drain pattern 150A and the upper source/drain pattern 150B. The connection electrode 199 may penetrate or extend into any one of the upper source/drain patterns 150B in the third direction D3. The connection electrode 199 may penetrate or extend into any one of the upper source/drain patterns 150B in the third direction D3 and extend in the direction of the upper surface of the substrate 101. One end of the connection electrode 199 extending in the direction of the upper surface of the substrate 101 may be connected (e.g., physically and/or electrically) to any one of the lower source/drain patterns 150A. One end of the connection electrode 199 extending in the upper surface direction of the substrate 101 may be connected (e.g., physically and/or electrically) to the upper surface of the lower source/drain pattern 150A directly below the upper source/drain pattern 150B penetrated by the connection electrode 199. In other words, the connection electrode 199 may extend into the upper source/drain pattern 150B. In the embodiments, the connection electrode 199 may penetrate or extend into at least a partial region of the upper etch stop film 185B positioned on the upper surface and the lower surface of the upper source/drain pattern 150B. In the embodiments, the connection electrode 199 may penetrate or extend into at least a partial region of the lower etch stop film 185A covering or overlapping the upper surface of the lower source/drain pattern 150A.

Referring to FIGS. 1, 2, and 6, a partial region of the side surface of the connection electrode 199 may be surrounded by the upper source/drain pattern 150B. In the embodiments, a partial region of the connection electrode 199 positioned at a level higher than the upper surface of the upper source/drain pattern 150B may be surrounded by a protection pattern 187 which will be described later. A partial region of the side surface of the connection electrode 199 may be surrounded by an air gap AG between the upper surface of the lower source/drain pattern 150A and the lower surface of the upper source/drain pattern 150B. The air gap AG may be positioned between the connection electrode 199 and the intermediate insulation pattern 181 and between the connection electrode 199 and the second interlayer insulation layer 173 between the upper surface of the lower source/drain pattern 150A and the lower surface of the upper source/drain pattern 150B.

Unlike the illustration in FIG. 2 and FIG. 6, the air gap AG may not be positioned around the connection electrode 199 between the upper surface of the lower source/drain pattern 150A and the lower surface of the upper source/drain pattern 150B. In this case, the connection electrode 199 or the second interlayer insulation layer 173 may be positioned at a portion where the air gap AG was positioned. In this case, a partial region of the side surface of the connection electrode 199 may be in contact with the second interlayer insulation layer 173 between the upper surface of the lower source/drain pattern 150A and the lower surface of the upper source/drain pattern 150B.

The upper surface of the connection electrode 199 may be positioned on the same plane as the upper surface of the capping layer 166, the upper surface of the gate spacer 164, and the upper surface of the second interlayer insulation layer 173.

Referring to FIGS. 2 and 6, the connection electrode 199 may be positioned to recess the lower source/drain pattern 150A to a predetermined depth. For example, the connection electrode 199 may penetrate or extend into partial regions of the lower etch stop film 185A and the upper etch stop film 185B that are positioned on the upper surface of the lower source/drain pattern 150A, and may extend to the inside of the lower source/drain pattern 150A by a predetermined depth. In this case, a portion of the side surface and the lower surface of the connection electrode 199 may be in contact with the upper surface of the upper source/drain pattern 150B.

In the embodiments, a width of the connection electrode 199 in a horizontal direction (e.g., the first direction D1 and/or the second direction D2) may not be constant. Referring to FIG. 3, the connection electrode 199 may include a first portion 199A, which overlaps the first protection pattern 187A in a horizontal direction, and a second portion 199B, which overlaps the second protection pattern 187B in a horizontal direction. In the embodiments, a width W1 of the first portion 199A in the horizontal direction may be greater than a width W2 of the second portion 199B in the horizontal direction. However, the present disclosure is not limited thereto, and a width of the first portion 199A in the horizontal direction may be substantially the same as a width of the second portion 199B in the horizontal direction. For example, when a width of the first protection pattern 187A and a width of the second protection pattern 187B, which are to be described below, are substantially the same, the widths of the first portion 199A and the second portion 199B in the horizontal direction may be substantially the same. Unlike the illustration in FIG. 2 and FIG. 6, the connection electrode 199 may have an inclined side surface in which a width of a lower portion becomes narrower than a width of an upper portion according to an aspect ratio.

Although not clearly illustrated in FIGS. 1 to 6, the connection electrode 199 may be connected to an external terminal to receive a voltage (or current) from the outside or provide a voltage (or current) to the outside. For example, the connection electrode 199 may be connected to an output terminal.

The connection electrode 199 may include a conductive material. For example, the connection electrode 199 may include at least one of a metal, a metal alloy, a conductive metal nitride, a conductive metal carbide, a conductive metal oxide, and/or a conductive metal carbon nitride.

In the embodiments, by electrically connecting the lower source/drain pattern 150A and the upper source/drain pattern 150B to each other through the connection electrode 199 penetrating or extending into the upper source/drain pattern 150B, a process margin may be improved when the semiconductor device is manufactured as illustrated in FIGS. 1 to 6.

The semiconductor device according to the embodiments may further include the upper contact electrode 191. The upper contact electrode 191 may be positioned on the upper source/drain pattern 150B. The upper contact electrode 191 may be positioned on another upper source/drain pattern 150B adjacent to the upper source/drain pattern 150B penetrated by the connection electrode 199. The upper contact electrode 191 may be positioned between two main gate structures 160M spaced apart from each other in the first direction D1. The upper contact electrode 191 may be in contact with a side surface of the protection pattern 187 to be described later. As illustrated in FIG. 2, in the region in which the upper contact electrode 191 is in contact with the protection pattern 187, a width of the upper contact electrode 191 in the horizontal direction (e.g., the first direction D1 or the second direction D2) may be constant. In another embodiments, unlike the illustration in FIG. 2, the width of the upper contact electrode 191 in the horizontal direction may not be constant. For example, the upper contact electrode 191 may have an inclined side surface at which a width of a lower portion becomes narrower than that of an upper portion according to an aspect ratio. For example, a width of the upper contact electrode 191 in the horizontal direction may have a shape that becomes narrower toward an upper surface of the upper source/drain pattern 150B. In this case, at least a portion of the side surface of the upper contact electrode 191 may not be in contact with the protection pattern 187. In the embodiments, the upper surface of the upper contact electrode 191 may be positioned on the same plane as the upper surfaces of the capping layer 166 and the gate spacer 164.

Referring to FIGS. 2 and 4, the upper contact electrode 191 may be positioned to recess the upper source/drain pattern 150B to a predetermined depth. For example, the upper contact electrode 191 may penetrate or extend into a partial region of the upper etch stop film 185B positioned on the upper surface of the upper source/drain pattern 150B and extend to the inside of the upper source/drain pattern 150B by a predetermined depth. In this case, a portion of the side surface and the lower surface of the upper contact electrode 191 may be in contact with the upper surface of the upper source/drain pattern 150B.

The upper contact electrode 191 may include a conductive material. For example, the upper contact electrode 191 may include at least one of a metal, a metal alloy, a conductive metal nitride, a metal silicide, a doped semiconductor material, a conductive metal oxide, and/or a conductive metal nitric oxide.

Although not clearly illustrated in FIGS. 1 to 6, the upper contact electrode 191 may be electrically connected to an external terminal to receive a voltage (or current) from the outside or provide a voltage (or current) to the outside. For example, the upper contact electrode 191 may be electrically connected to a ground or an external input terminal.

Although not clearly illustrated in FIGS. 1 to 6, the semiconductor device according to the embodiments may further include a lower contact electrode connected to any one of the lower source/drain patterns 150A. In this case, the lower contact electrode may penetrate or extend into at least a partial region of the dummy semiconductor pattern 143 to be connected to a lower surface of the lower source/drain pattern 150A.

The protection pattern 187 may be positioned between the gate structure 160 and the connection electrode 199. The protection pattern 187 may protect configurations around the connection electrode 199, for example, the main gate structure 160, the gate spacer 164, and the capping layer 166, from being damaged by an etching material in the process of forming the connection electrode 199.

The protection pattern 187 may surround at least a portion of a side surface of the connection electrode 199. Referring to FIG. 2, the protection pattern 187 may surround at least a portion of a side surface of the connection electrode 199 positioned at a higher level than the interface between the main gate structure 160M and the upper channel pattern 140B. Referring to FIG. 2, the protection pattern 187 may be positioned between the main gate structure 160M and the connection electrode 199. The protection pattern 187 may be positioned between the gate spacer 164 and the connection electrode 199. An upper etch stop film 185B may be interposed between the protection pattern 187 and one side surface of the gate spacer 164. The protection pattern 187 may also be positioned between the second interlayer insulation layer 173 and the connection electrode 199. The protection pattern 187 may surround at least a partial region of a side surface of the connection electrode 199 positioned at a higher level than the upper surface of the upper etch stop film 185B covering the upper surface of the upper source/drain pattern 150B, on a cross-sectional view of FIG. 6.

In the embodiments, the protection pattern 187 may include a first protection pattern 187A and a second protection pattern 187B. The second protection pattern 187B may be positioned on the first protection pattern 187A. Referring to FIGS. 2 and 6, the first protection pattern 187A may be positioned between the lower portion of the main gate structure 160M and the connection electrode 199, and the second protection pattern 187B may be positioned between the upper portion of the main gate structure 160M and the connection electrode.

The protection pattern 187 may extend along the third direction D3. In the embodiments, lengths of the first protection pattern 187A and the second protection pattern 187B extending along the third direction D3 may be different from each other. For example, the length of the second protection pattern 187B extending along the third direction D3 may be longer than the length of the first protection pattern 187A extending along the third direction D3. In the embodiments, the ratio of the length of the second protection pattern 187B extending along the third direction D3 to the length of the first protection pattern 187A extending along the third direction D3 may be greater than or equal to about 1, or less than or equal to about 5.

In the embodiments, the widths of the first protection pattern 187A and the second protection pattern 187B in the horizontal direction (e.g., the first direction D1 or the second direction D2) may be different from each other. In the embodiments, the width of the second protection pattern 187B in the horizontal direction may be greater than the width of the first protection pattern 187A in the horizontal direction. However, the present disclosure is not limited thereto, and the widths of the first protection pattern 187A and the second protection pattern 187B in the horizontal direction may be substantially the same.

In the embodiments, the first protection pattern 187A may include a high-k dielectric material. The high-k dielectric material may refer to, for example, a material having a higher dielectric constant compared to a dielectric constant of silicon oxide (SiO₂). For example, the first protection pattern 187A may include at least one of Al₂O₃, CaF, Y₂O₃, ZrO₂, HfO₂, and/or MgO. In the embodiments, the high-k dielectric material included in the first protection pattern 187A may have lower etch selectivity than the insulating material included in the gate spacer 164, the capping layer 166, and the upper etch stop film 185B. As illustrated in FIG. 2 and FIG. 6, when the first protection pattern 187A including the high-k dielectric material is positioned between the gate structure 160 and the connection electrode 199, in the process of forming the connection electrode 199, configurations around the connection electrode 199, for example, the main gate structure 160, the gate spacer 164, and the capping layer 166, may be well protected so as not to be damaged by the etching material. Also, since the first protection pattern 187A has the low etch selectivity, the first protection pattern 187A may be formed to have a thin thickness, and thus the connection electrode 199 may be formed to have a wide width in at least some regions, thereby improving the electrical characteristics of the semiconductor device according to the embodiments.

In the embodiments, the second protection pattern 187B may include a low-k dielectric material. The low-k dielectric material may mean, for example, a material having a lower dielectric constant compared to a dielectric constant of silicon oxide (SiO₂). For example, the second protection pattern 187B may include at least one of SiOCN, SiCN, SiBCN, and BN. When a high-k dielectric material such as that included in the first protection pattern 187A is positioned around the connection electrode 199, parasitic capacitance around the connection electrode 199 may increase, and thus electrical characteristics of the semiconductor device according to the embodiments may be deteriorated. In a process of manufacturing the semiconductor device according to the embodiments, at least a partial region of the first protection pattern 187A may be replaced with the second protection pattern 187B after the connection electrode 199 is formed. In this case, parasitic capacitance around the connection electrode 199 decreases, and thus electrical characteristics of the semiconductor device according to the embodiments may be improved.

Referring to FIGS. 2 and 4, in the semiconductor device according to the embodiments, the protection pattern 187 may also be positioned between the gate structure 160 and the upper contact electrode 191. A detailed structure of the protection pattern 187 between the gate structure 160 and the upper contact electrode 191, a material included in the protection pattern 187, effects of the protection pattern 187 and the like are similar to those of the protection pattern 187 positioned between the gate structure 160 and the connection electrode 199, and thus a detailed description thereof will be omitted.

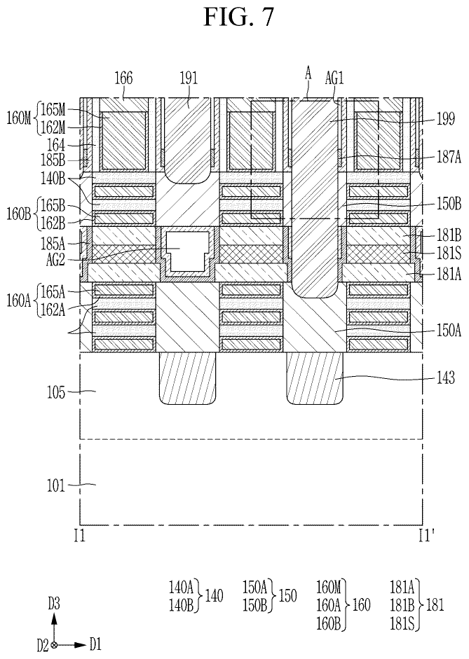

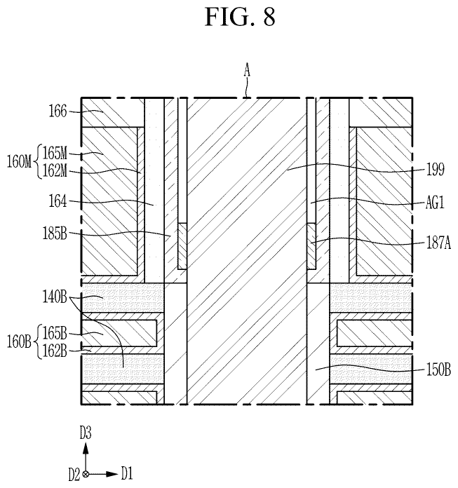

FIGS. 7 and 8 are diagrams for illustrating a semiconductor device according to some embodiments. Specifically, FIG. 7 is a cross-sectional view of the semiconductor device taken along line I1-I1′ of FIG. 1, and FIG. 8 is an enlarged cross-sectional view of a region ‘A’ of FIG. 7. Since the semiconductor device illustrated in FIGS. 7 and 8 has substantially the same points as those of the previous embodiments, differences from the previous embodiments will be mainly described below. Specifically, the semiconductor device illustrated in FIGS. 7 and 8 may be partially different from the previous embodiments in that an air gap AG is included around the connection electrode 199.

The semiconductor device according to the embodiments may include a first air gap AG1 and a second air gap AG2. Referring to FIGS. 7 and 8, the first air gap AG1 may surround at least a portion of a side surface of the connection electrode 199.

The first air gap AG1 may be positioned on the first protection pattern 187A. The first air gap AG1 may be positioned between the main gate structure 160M and the connection electrode 199. The first air gap AG1 may be positioned between the gate spacer 164 and the connection electrode 199. The upper etch stop film 185B may be interposed between the first air gap AG1 and one side surface of the gate spacer 164. The first air gap AG1 may also be positioned between the second interlayer insulation layer 173 and the connection electrode 199.

The first air gap AG1 may replace at least a portion of a region where the second protection pattern 187B was positioned in the semiconductor device described with reference to FIGS. 1 to 6. In the embodiments, a width of the first air gap AG1 in the horizontal direction (e.g., the first direction D1 or the second direction D2) may be substantially the same as a width of the first protection pattern 187A in the horizontal direction.

In the case of the second air gap AG2, a position and effect in the semiconductor device according to the embodiments are similar to those of the air gap AG described with reference to FIGS. 1 to 6, and thus a detailed description thereof will be omitted.

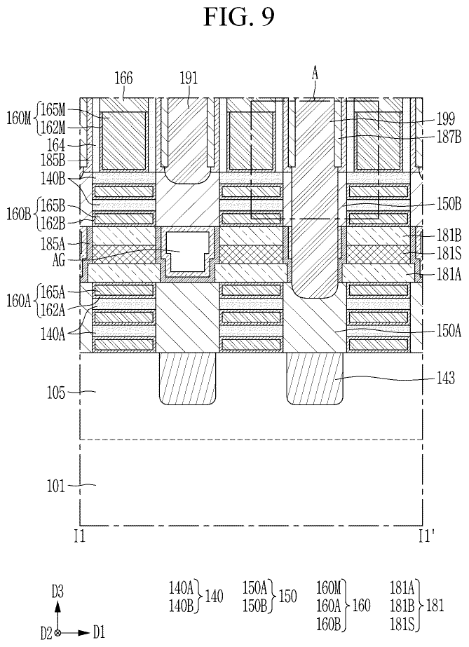

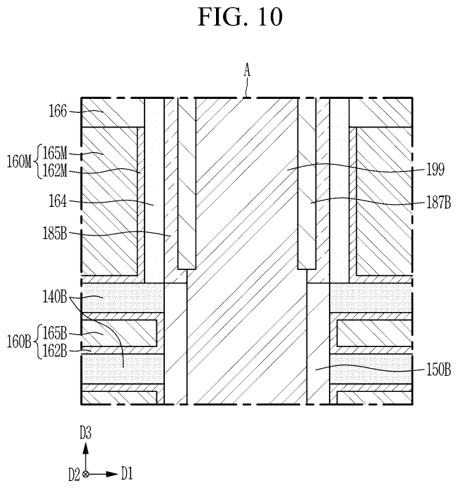

FIGS. 9 and 10 are diagrams for illustrating a semiconductor device according to some embodiments. Specifically, FIG. 9 is a cross-sectional view of the semiconductor device taken along line I1-I1′ of FIG. 1, and FIG. 10 is an enlarged cross-sectional view of a region ‘A’ of FIG. 9. Since the semiconductor device illustrated in FIGS. 9 and 10 has substantially the same points as those of the previous embodiments, differences from the previous embodiments will be mainly described below. Specifically, the semiconductor device illustrated in FIGS. 9 and 10 may be partially different from the previous embodiments in that the first protection pattern 187A is not included around the connection electrode 199.

A high-k dielectric material may not be included around the connection electrode 199 of the semiconductor device according to the embodiments. Referring to FIGS. 9 and 10, the semiconductor device according to the embodiments may not include the first protection pattern 187A described with reference to FIGS. 1 to 6.

In the semiconductor device according to the embodiments, the region in which the first protection pattern 187A was positioned in the semiconductor device described with reference to FIGS. 1 to 6 may be replaced by the second protection pattern 187B.

In the process of manufacturing the semiconductor device according to the embodiments, after the connection electrode 199 is formed, the first protection pattern 187A may be completely etched, and a region where the first protection pattern 187A was positioned may be filled with the second protection pattern 187B. According to the embodiments, the parasitic capacitance around the connection electrode 199 may be further reduced compared to the semiconductor device described with reference to FIGS. 1 to 6, and thus the electrical characteristics of the semiconductor device may be improved.

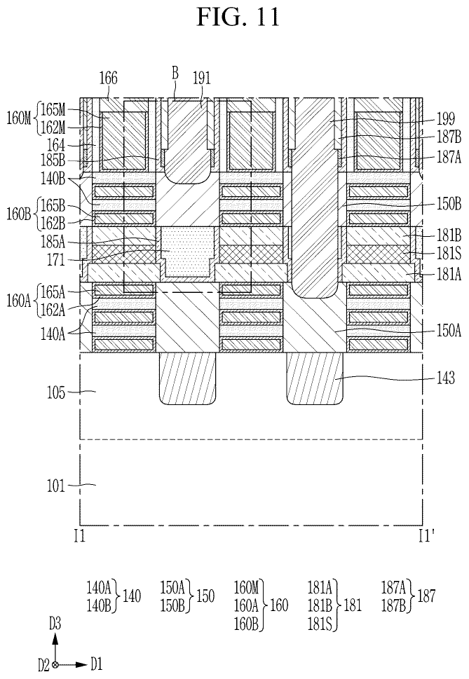

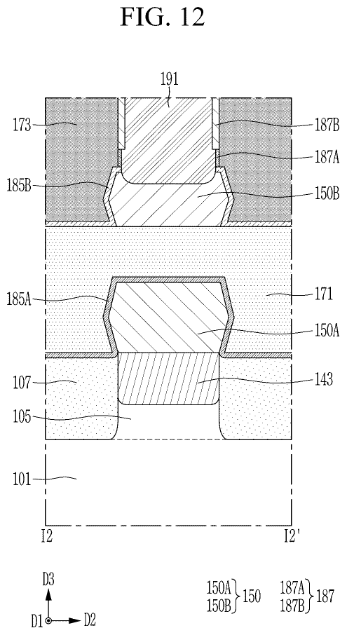

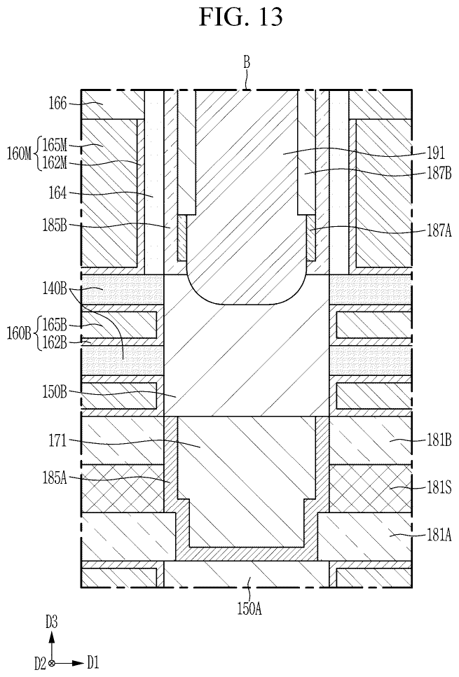

FIGS. 11 to 13 are diagrams for illustrating a semiconductor device according to some embodiments. Specifically, FIG. 11 is a cross-sectional view of the semiconductor device taken along line I1-I1′ of FIG. 1, FIG. 12 is a cross-sectional view of the semiconductor device taken along line I2-I2′ of FIG. 1, and FIG. 13 is an enlarged cross-sectional view of a region ‘B’ of FIG. 11. Since the semiconductor device illustrated in FIGS. 11 to 13 has substantially the same points as those of the previous embodiments, differences from the previous embodiments will be mainly described below. Specifically, the semiconductor device illustrated in FIGS. 11 to 13 may not include an air gap between the lower source/drain pattern 150A and the upper source/drain pattern 150B, which may be partially different from the previous embodiments.

Referring to FIGS. 11 to 13, in the semiconductor device according to embodiments, the first interlayer insulation layer 171 may be positioned between the lower source/drain pattern 150A and the upper source/drain pattern 150B. The first interlayer insulation layer 171 may be positioned between two intermediate insulation patterns 181 that are adjacent to each other along the first direction D1. Referring to FIGS. 11 to 13, the lower etch stop film 185A may be interposed between the first interlayer insulation layer 171 and the intermediate insulation pattern 181. The lower etch stop film 185A may be interposed between upper and side surfaces of the first interlayer insulation layer 171 and the lower source/drain pattern 150A.

In the semiconductor device according to the embodiments, the upper etch stop film 185B may not be positioned on the lower surface of the upper source/drain pattern 150B. In the embodiments, the lower surface of the upper source/drain pattern 150B may be covered or overlapped by the first interlayer insulation layer 171.

In the embodiments, the second interlayer insulation layer 173 may not be positioned below the lower surface of the upper source/drain pattern 150B. In the embodiments, the upper etch stop film 185B may not be positioned below the lower surface of the upper source/drain pattern 150B.

In the embodiments, the first interlayer insulation layer 171 may include a low-k dielectric material. For example, the first interlayer insulation layer 171 may include at least one of SiOCN, SiCN, SiBCN, and/or BN. However, the present disclosure is not limited thereto, and the first interlayer insulation layer 171 may include another insulating material, for example, silicon oxide (SiO₂).

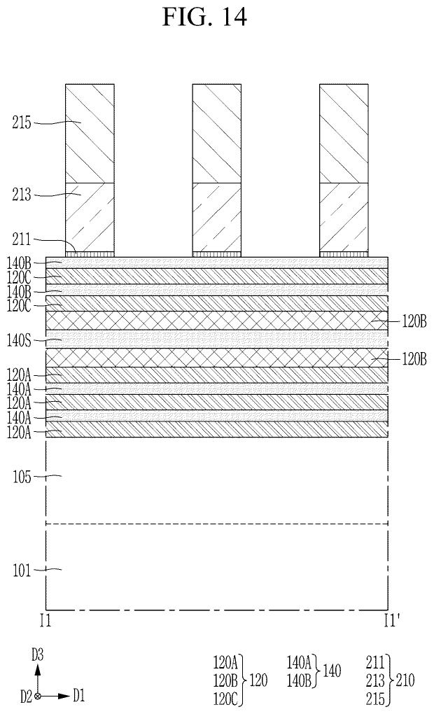

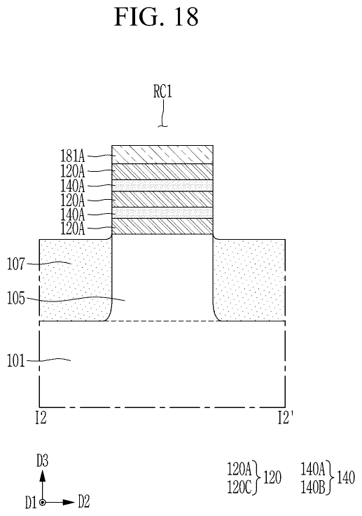

FIGS. 14 to 49 are process cross-sectional views illustrating a method of manufacturing a semiconductor device according to some embodiments. FIGS. 14 to 17, 19 to 21, 23 to 27, 29, 31, 32, 34, 36, and 38 to 49 are cross-sectional views of the region taken along line I-I′ of FIG. 1, illustrating a method of manufacturing a semiconductor device according to some embodiments. FIGS. 18, 22, 28, 30, 33, 35, and 37 are cross-sectional views of the region taken along line I2-I2′ of FIG. 1, illustrating a method of manufacturing a semiconductor device according to some embodiments.

As illustrated in FIG. 14, sacrificial layers 120, a plurality of lower channel patterns 140A, an intermediate semiconductor pattern 140S, and a plurality of upper channel patterns 140B may be formed on a substrate 101.

First, sacrificial layers 120, a plurality of lower channel patterns 140A, an intermediate semiconductor pattern 140S, and a plurality of upper channel patterns 140B are formed on a substrate 101. The substrate 101 may be silicon-on-insulator (SOI) or bulk silicon. In some embodiments, the substrate 101 may be a silicon substrate or may include other materials, such as, silicon germanium (SiGe), silicon germanium on insulator (SGOI), indium antimonide, lead telluride compound, indium arsenide, indium phosphide, gallium arsenide, or gallium antimonide, but is not limited thereto.

The sacrificial layers 120 may include lower sacrificial layers 120A, intermediate sacrificial layers 120B, and upper sacrificial layers 120C. In the embodiments, the lower sacrificial layer 120A may be alternately stacked with the lower channel patterns 140A, and the upper sacrificial layers 120C may be alternately stacked with the upper channel patterns 140B. The intermediate sacrificial layers 120B may be positioned on an upper surface and a lower surface of the intermediate semiconductor pattern 140S.

The sacrificial layers 120A, 120B, and 120C may be formed of a material having etching selectivity with respect to the plurality of lower channel patterns 140A, the intermediate semiconductor pattern 140S, and the plurality of upper channel patterns 140B. The plurality of lower channel patterns 140A, the intermediate semiconductor pattern 140S, and the plurality of upper channel patterns 140B may include a material different from that of the sacrificial layers 120A, 120B, and 120C. For example, the plurality of lower channel patterns 140A, the intermediate semiconductor pattern 140S, and the plurality of upper channel patterns 140B may include silicon (Si), and the sacrificial layers 120 may include silicon germanium (SiGe). In the embodiments, the intermediate sacrificial layers 120B may have etching selectivity with respect to other sacrificial layers 120A and 120C. In the embodiments, the intermediate sacrificial layers 120B may have different concentrations of germanium (Ge) compared to the lower sacrificial layer 120A and the upper sacrificial layer 120C.

The sacrificial layers 120, the plurality of lower channel patterns 140A, and the plurality of upper channel patterns 140B may be formed by performing an epitaxial growth process using the substrate 101 as a seed. The numbers of the plurality of lower channel patterns 140A, intermediate semiconductor patterns 140S, and the plurality of upper channel patterns 140B, which are alternately stacked with the sacrificial layers 120, may be variously changed in embodimentss.

Next, portions of the sacrificial layers 120, the plurality of lower channel patterns 140A, the intermediate semiconductor pattern 140S, the plurality of upper channel patterns 140B, and the substrate 101 may be removed to form an active structure, and a field insulation layer 107 (see FIG. 4) may be formed. The active structure may include the sacrificial layers 120, the plurality of lower channel patterns 140A, the intermediate semiconductor pattern 140S, and the plurality of upper channel patterns 140B, which are alternately stacked. Also, the active structure may further include an active pattern 105 formed to protrude from the upper surface of the substrate 101 by removing at least a portion of the substrate 101. The active structure may extend in the first direction D1. The active structures may be positioned to be spaced apart from each other in the second direction D2. Accordingly, opposite side surfaces of the intermediate sacrificial layer 120B and the intermediate semiconductor pattern 140S may be exposed.

The field insulation layer 107 (refer to FIG. 4) may be formed in a portion from which at least a portion of the substrate 101 is removed. Accordingly, the active pattern 105 may be positioned on the side surface of the field insulation layer 107.

Next, a sacrificial gate structure 210 may be formed on the active structure. The sacrificial gate structure 210 may include first and second sacrificial gate electrodes 211 and 213 and a preliminary capping layer 215 sequentially positioned on the plurality of upper channel patterns 140B. The first sacrificial gate electrode 211 may include, for example, silicon oxide (SiO₂), but is not limited thereto. The second sacrificial gate electrode 213 may include, for example, polysilicon, but is not limited thereto. The preliminary capping layer 215 may include, for example, silicon nitride, but is not limited thereto. Accordingly, opposite side surfaces of a portion of the intermediate sacrificial layer 120B positioned between the sacrificial gate structures 210 and opposite side surfaces of a portion of the intermediate semiconductor pattern 140S may be exposed.

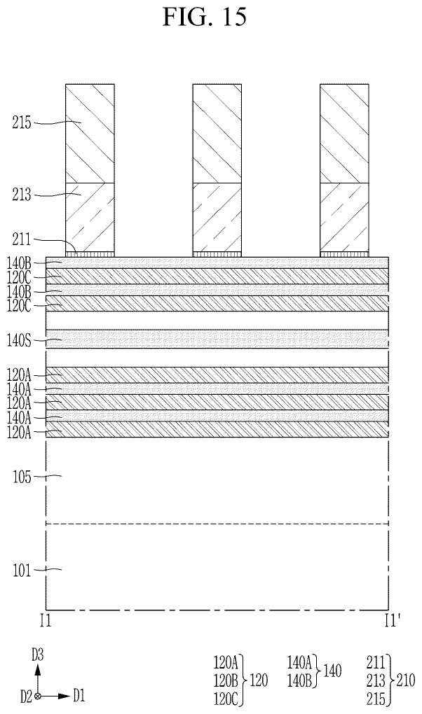

Next, as illustrated in FIG. 15, the intermediate sacrificial layers 120B among the plurality of sacrificial layers 120 may be selectively removed. The intermediate sacrificial layer 120B may be removed through opposite side surfaces of the exposed intermediate sacrificial layer 120B and the intermediate semiconductor pattern 140S. The process of removing the intermediate sacrificial layers 120B may be performed by an etching material having a higher etching rate with respect to the intermediate sacrificial layer 120B as compared with the lower sacrificial layer 120A, the upper sacrificial layer 120C, and the channel patterns 140A and 140B.

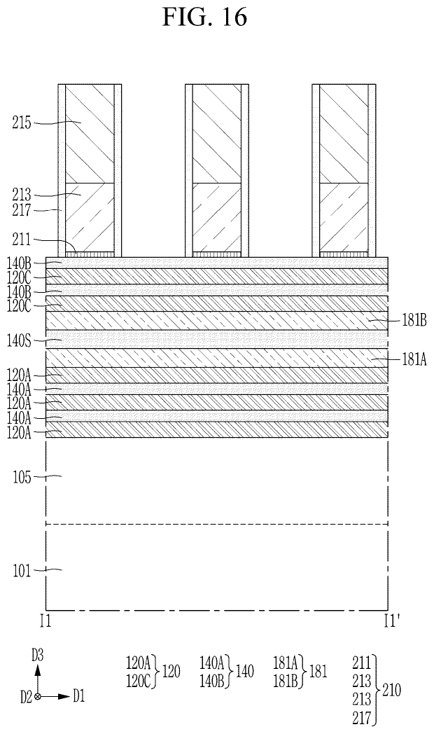

As illustrated in FIG. 16, a first intermediate insulation pattern 181A and a second intermediate insulation pattern 181B may be formed in a region from which the intermediate sacrificial layers 120B are removed. In the embodiments, the first intermediate insulation pattern 181A and the second intermediate insulation pattern 181B may include a material having etch selectivity with respect to the intermediate semiconductor pattern 140S. For example, the intermediate insulation patterns 181A and 181B may include silicon nitride (SiNₓ), but are not limited thereto.

Subsequently, a preliminary gate spacer 217 may be formed to cover or overlap opposite side surfaces of the sacrificial gate structure 210. The preliminary gate spacer 217 may be formed to have a uniform thickness along the upper and side surfaces of the sacrificial gate structure 210 and the active structure. First, after the preliminary gate spacer 217 is formed to cover or overlap the entire upper and side surfaces of the sacrificial gate structure 210, a partial region of the preliminary gate spacer 217 positioned on the upper surface of the sacrificial gate structure 210 may be etched by a dry etching process.

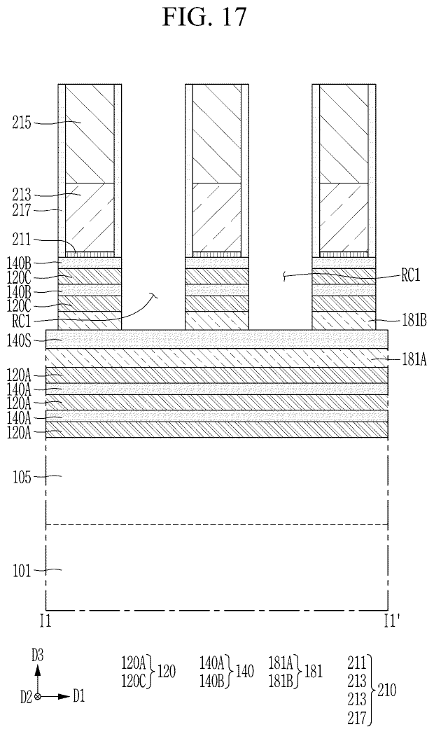

Next, as illustrated in FIGS. 17 and 18, a first recess RC1 exposing a portion of the intermediate semiconductor pattern 140S may be formed by removing a partial region of the upper sacrificial layer 120C and the upper channel pattern 140B. The process of forming the first recess RC1 may be performed by a dry etching process using the sacrificial gate structures 210 as etching masks. Referring to FIG. 17, a partial region of the upper channel pattern 140B and the upper sacrificial layer 120C positioned between the sacrificial gate structures 210 which are spaced apart from each other in the first direction D1 may be etched, and accordingly, a partial region of the upper surface of the intermediate semiconductor pattern 140S may be exposed.

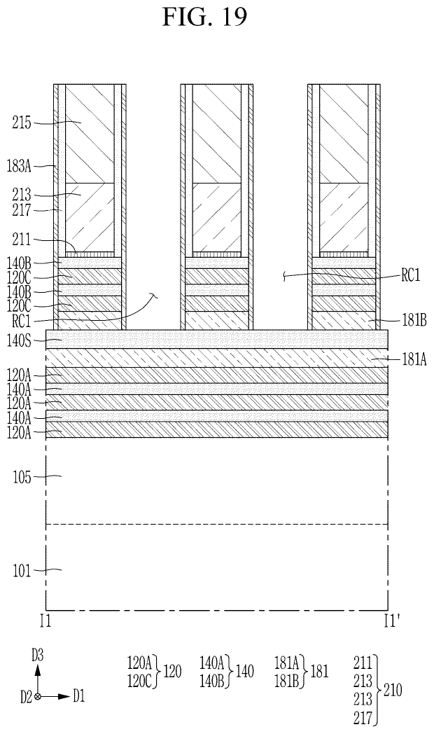

As illustrated in FIG. 19, a first barrier pattern 183A covering or overlapping a side surface of the first recess RC1 may be formed. The first barrier pattern 183A may be formed by conformally depositing an insulating material inside the first recess RC1 and on the upper surface of the sacrificial gate structure 210, and then removing the insulating material positioned on the upper surface of the sacrificial gate structure 210 and the lower surface of the first recess RC1 by a dry etching process. The first barrier pattern 183A may include a material having etch selectivity with respect to the intermediate semiconductor pattern 140S.

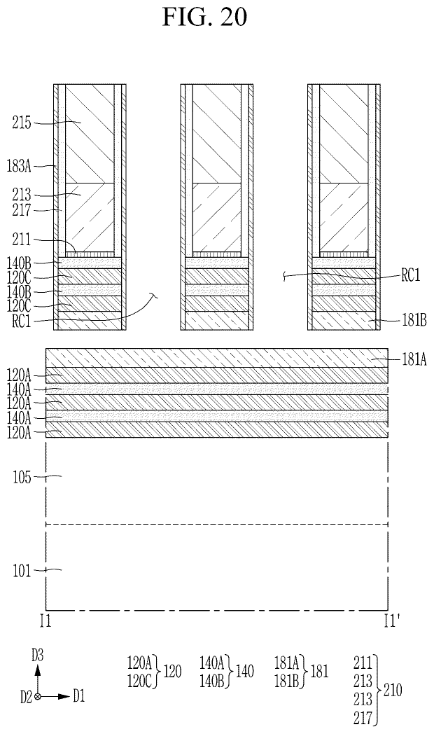

Next, as illustrated in FIG. 20, the intermediate semiconductor pattern 140S may be etched through the region exposed by the first recess RC1. In this case, the sacrificial gate structure 210, the upper channel patterns 140B, and the upper sacrificial layer 120C may be protected by the first barrier pattern 183A. Since the first intermediate insulation pattern 181A and the second intermediate insulation pattern 181B have etch selectivity with respect to the intermediate semiconductor pattern 140S, the first intermediate insulation pattern 181A and the second intermediate insulation pattern 181B may not be etched, or may not be etched only by a very small amount.

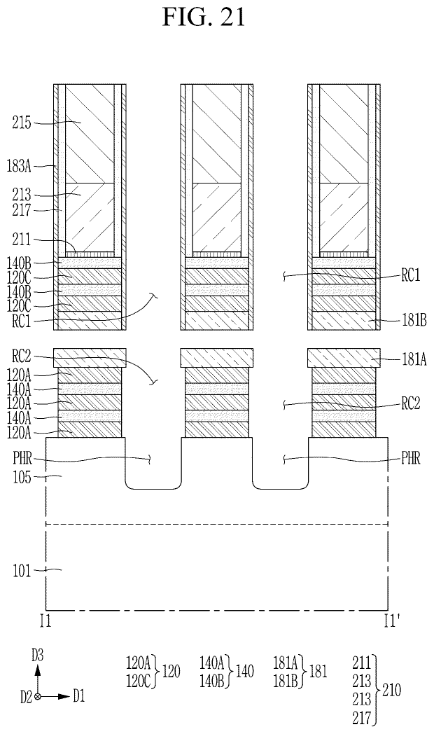

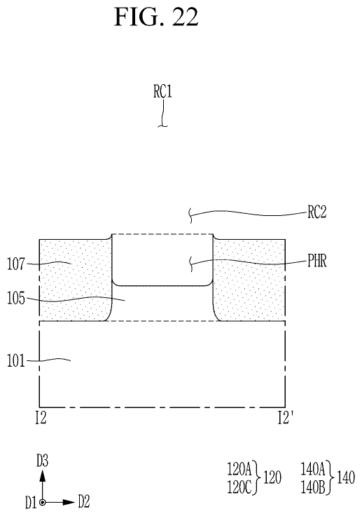

As illustrated in FIGS. 21 and 22, a second recess RC2 and a lower recess PHR may be formed by etching partial regions of the first intermediate insulation pattern 181A, the lower sacrificial layer 120A, the lower channel pattern 140A, and the active pattern 105. The process of forming the second recess RC2 and the lower recess PHR may be performed by an anisotropic etching process. In this case, the sacrificial gate structure 210 may be used as a mask. In this case, the upper channel pattern 140B, the upper sacrificial layer 120C, and the second intermediate insulation pattern 181B may be protected by the first barrier pattern 183A without being etched.

The process of forming the second recess RC2 and the lower recess PHR may be sequentially performed. First, a partial region of the lower sacrificial layers 120A and the lower channel patterns 140A may be etched to form a second recess RC2, and then a lower recess PHR may be formed by etching a partial region of the active pattern 105. In this case, the lower recess PHR may be formed to have a narrower width in the first direction D1 than the second recess RC2. In this case, the process of forming the lower recess PHR may be controlled to have a higher etching rate with respect to the vertical direction as compared to the process of forming the second recess RC2.

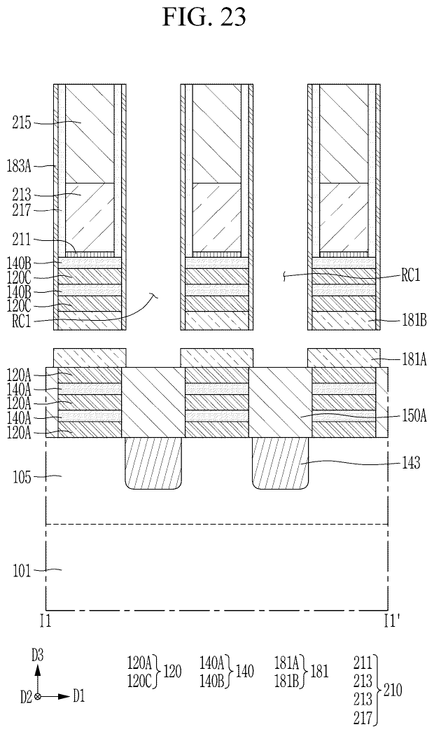

Next, as illustrated in FIG. 23, a dummy semiconductor pattern 143 and a lower source/drain pattern 150A may be formed in the lower recess PHR and the second recess RC2, respectively.

The dummy semiconductor pattern 143 may be formed by a selective epitaxial growth process by using the active pattern 105 positioned on the side surface and the lower surface of the lower recess PHR as a seed. Accordingly, the side surface and the lower surface of the dummy semiconductor pattern 143 may be in contact with the active pattern 105.

The lower source/drain pattern 150A may be formed by a selective epitaxial growth process using the upper surface of the dummy semiconductor pattern 143 and the plurality of lower channel patterns 140A as seeds. The lower source/drain pattern 150A may be formed in the second recess RC2. The side surface and the lower surfaces of the lower source/drain pattern 150A may be in contact with the side surfaces of the plurality of lower channel patterns 140A and the upper surface of the dummy semiconductor pattern 143, respectively.

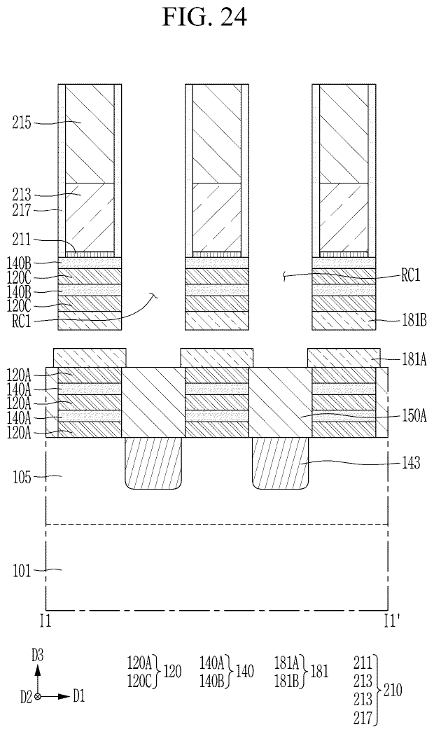

In the embodiments, the lower source/drain pattern 150A and the dummy semiconductor pattern 143 may include silicon germanium (SiGe). In the embodiments, silicon germanium (SiGe) included in the dummy semiconductor pattern 143 may have a higher germanium (Ge) concentration than the lower source/drain pattern 150A. Subsequently, as illustrated in FIG. 24, the first barrier pattern 183A may be removed.

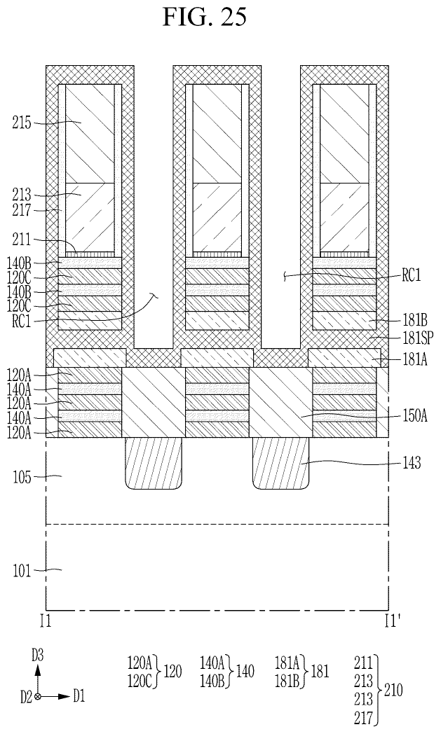

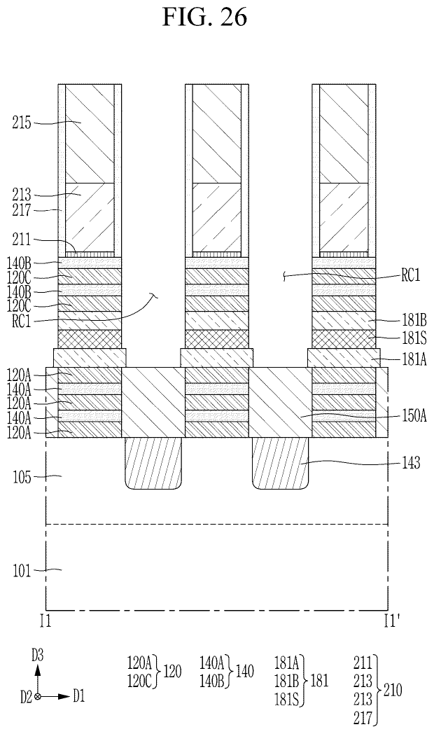

Next, a third intermediate insulation pattern 181S may be formed between the first intermediate insulation pattern 181A and the second intermediate insulation pattern 181B. First, as illustrated in FIG. 25, a preliminary third intermediate insulation pattern 181SP covering or overlapping the upper surface and the side surfaces of the sacrificial gate structure 210, the side surfaces of the upper channel patterns 140B, the side surfaces of the upper sacrificial layers 120C, the upper surfaces of the lower source/drain patterns 150A, and partial regions of the first intermediate insulation pattern 181A and the second intermediate insulation pattern 181B may be formed. In this case, the preliminary third intermediate insulation pattern 181SP may also be formed between the first intermediate insulation pattern 181A and the second intermediate insulation pattern 181B. Thereafter, as illustrated in FIG. 26, the remaining region of the preliminary third intermediate insulation pattern 181SP other than the region positioned between the first intermediate insulation pattern 181A and the second intermediate insulation pattern 181B may be etched by an anisotropic etching process to form a third intermediate insulation pattern 181S.

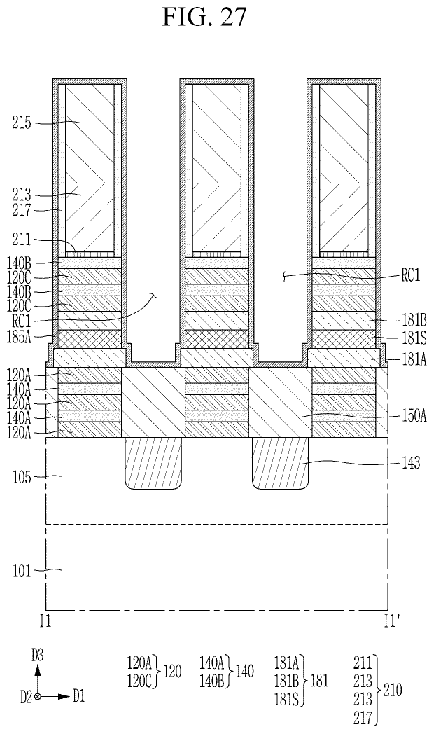

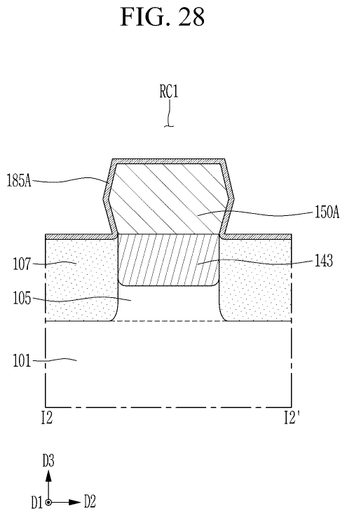

As illustrated in FIGS. 27 and 28, a lower etch stop film 185A covering or overlapping the sacrificial gate structure 210 and the lower source/drain pattern 150A may be formed. In the embodiments, the lower etch stop film 185A may be conformally formed on the upper surface and the side surface of the sacrificial gate structure 210, and on the upper surface and the side surface of the lower source/drain pattern 150A. Referring to FIG. 28, the lower etch stop film 185A may also be formed on the upper surface of the field insulation layer 107.

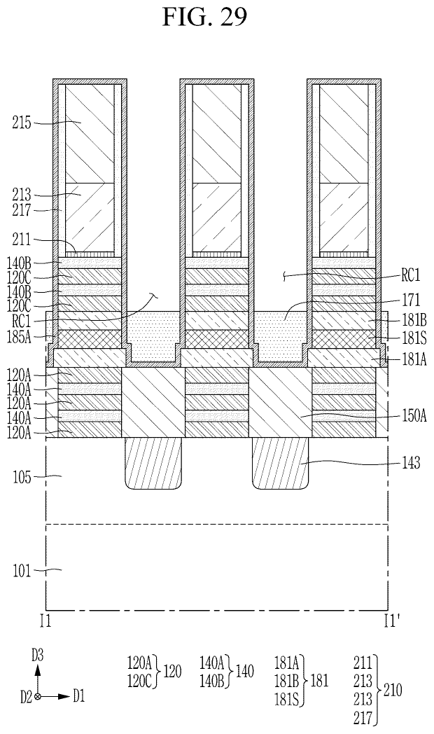

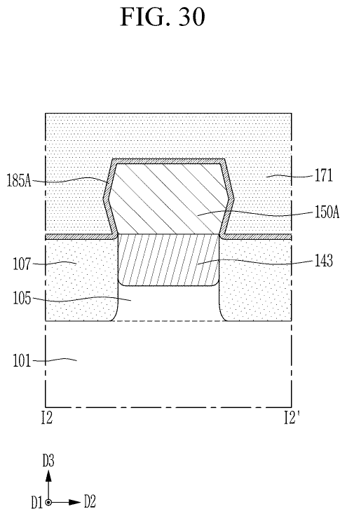

As illustrated in FIGS. 29 and 30, a first interlayer insulation layer 171 covering or overlapping the lower source/drain pattern 150A and the field insulation layer 107 may be formed. The first interlayer insulation layer 171 may be positioned on the upper surface of the field insulation layer 107, and the upper surface and the side surface of the lower source/drain pattern 150A. The first interlayer insulation layer 171 may cover or overlap a partial region of the lower etch stop film 185A. Referring to FIG. 30, the first interlayer insulation layer 171 may cover or overlap the lower etch stop film 185A, which is conformally formed on the upper surface of the field insulation layer 107, and the upper surface and the side surface of the lower source/drain pattern 150A.

The first interlayer insulation layer 171 may also be positioned on the side surface of the intermediate insulation pattern 181. Referring to FIG. 29, the first interlayer insulation layer 171 may be formed such that the upper surface is positioned on the same plane as the upper surface of the second intermediate insulation pattern 181B. However, the present disclosure is not limited thereto, and the upper surface of the first interlayer insulation layer 171 may be positioned at a lower level than the upper surface of the second intermediate insulation pattern 181B. For example, the upper surface of the first interlayer insulation layer 171 may be positioned between the upper surface of the second intermediate insulation pattern 181B and the lower surface of the first intermediate insulation pattern 181A.

In the embodiments, the upper surface of the first interlayer insulation layer 171 may not be positioned at a higher level than the upper surface of the second intermediate insulation pattern 181B. The first interlayer insulation layer 171 may be formed not to cover the side surfaces of the upper channel pattern 140B and the upper sacrificial layer 120C.

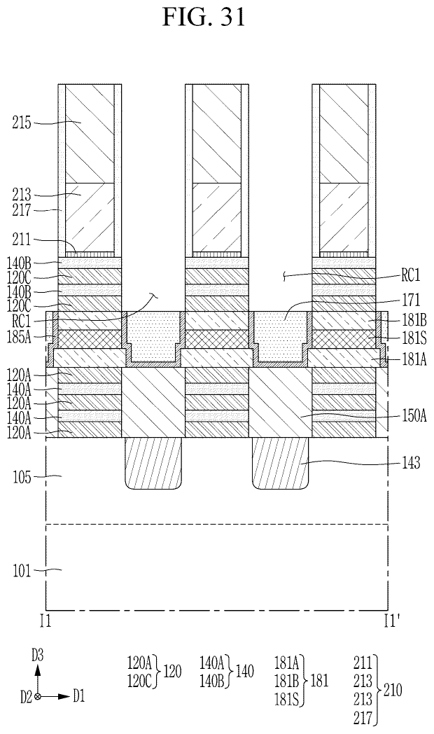

As illustrated in FIG. 31, a partial region of the lower etch stop film 185A may be etched. In the embodiments, the lower etch stop film 185A may be etched by using an etching material having higher etching selectivity with respect to the lower etch stop film 185A compared to the first interlayer insulation layer 171. Accordingly, as illustrated in FIG. 31, a partial region of the lower etch stop film 185A positioned at a higher level than the upper surface of the first interlayer insulation layer 171 may be removed from among the entire area of the lower etch stop film 185A. Accordingly, the upper surface of the lower etch stop film 185A may be positioned on the same plane as the upper surface of the first interlayer insulation layer 171. As the lower etch stop film 185A positioned at a higher level than the upper surface of the first interlayer insulation layer 171 is removed, side surfaces of the upper channel patterns 140B and the upper sacrificial layers 120C may be exposed.

Unlike the illustration in FIG. 31, when the upper surface of the first interlayer insulation layer 171 is positioned between the upper surface of the second intermediate insulation pattern 181B and the lower surface of the first intermediate insulation pattern 181A, a part of the side surface of the intermediate insulation pattern 181 may be exposed in the process of removing the lower etch stop film 185A. In this case, the lower etch stop film 185A may cover or overlap a partial region of the side surface of the intermediate insulation pattern 181. For example, the lower etch stop film 185A may cover or overlap the side surface of one or two of the first intermediate insulation pattern 181A, the second intermediate insulation pattern 181B, and the third intermediate insulation pattern 181S. For example, the lower etch stop film 185A may cover or overlap only at least a partial region of the side surface of the first intermediate insulation pattern 181A and the side surface of the third intermediate insulation pattern 181S. For example, the lower etch stop film 185A may cover or overlap only at least a partial region of the side surface of the first intermediate insulation pattern 181A.

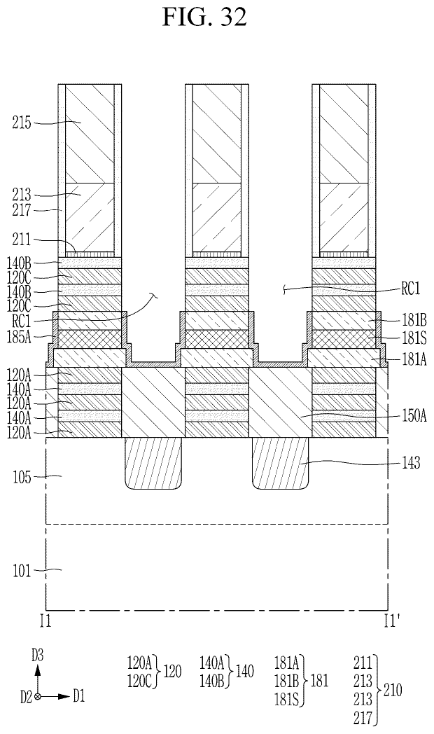

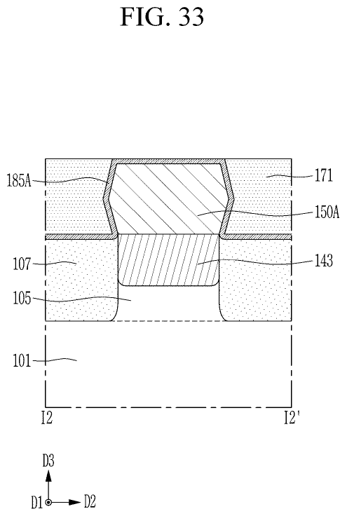

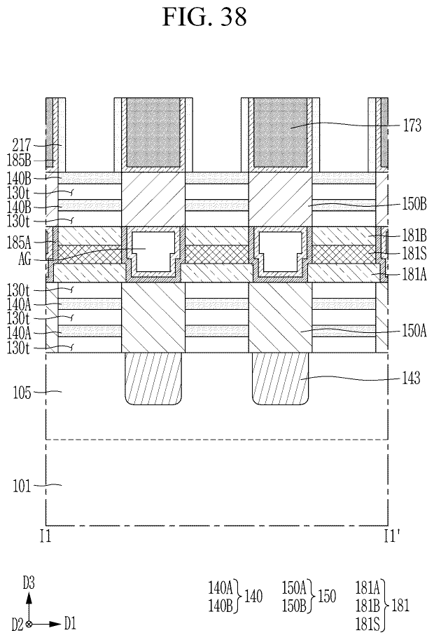

Subsequently, as illustrated in FIGS. 32 and 33, a partial region of the first interlayer insulation layer 171 may be etched by an etch back process. Referring to FIGS. 32 and 33, a partial region of the first interlayer insulation layer 171 positioned at a higher level than the upper surface of the lower etch stop film 185A covering the upper surface of the lower source/drain pattern 150A may be removed. In the embodiments, the first interlayer insulation layer 171 may be sufficiently removed so that an air gap AG (refer to FIG. 38) may be well formed on the lower source/drain pattern 150A in a subsequent process.

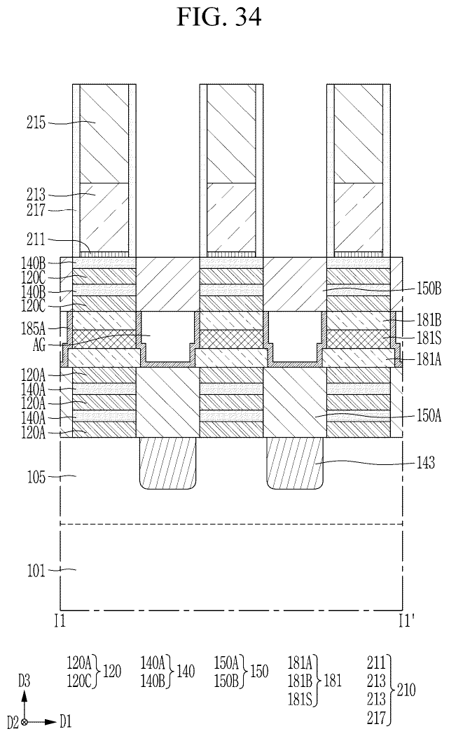

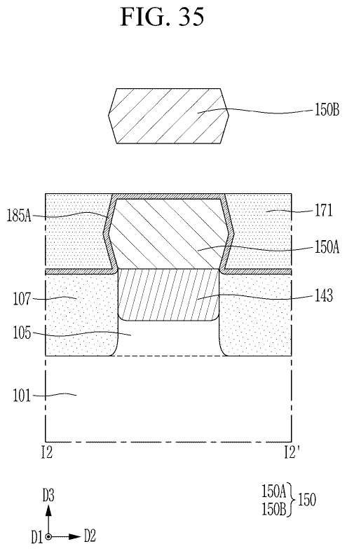

As illustrated in FIGS. 34 and 35, upper source/drain patterns 150B filling a partial region of the first recess RC1 may be formed. Specifically, upper source/drain patterns 150B may be formed on side surfaces of the first recess RC1 by using opposite side surfaces of the plurality of upper channel patterns 140B as seeds. In the embodiments, the upper source/drain pattern 150B may include silicon germanium (SiGe).

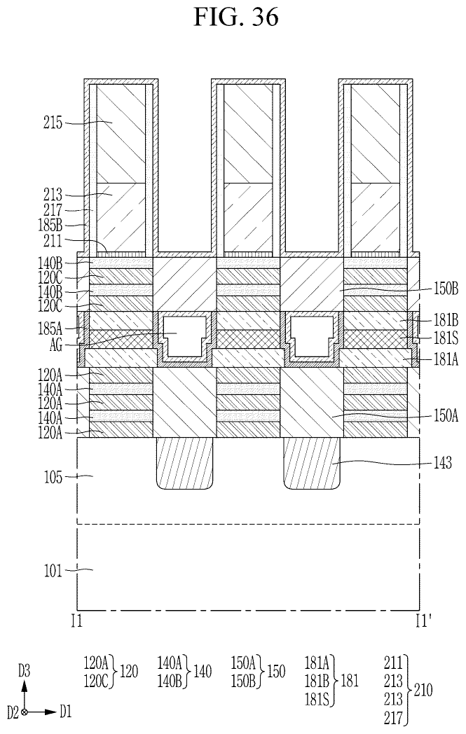

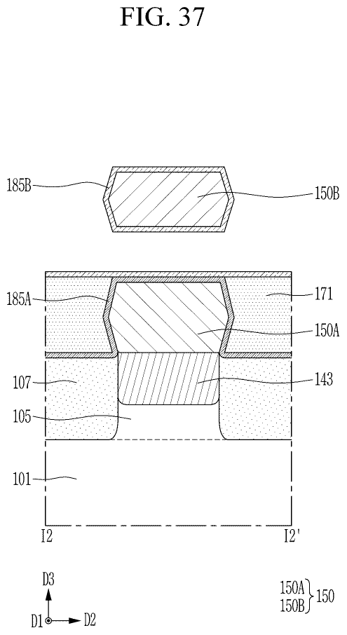

As illustrated in FIGS. 36 and 37, an upper etch stop film 185B covering or overlapping the sacrificial gate structure 210 and the upper source/drain pattern 150B may be formed. The upper etch stop film 185B may be conformally formed along the upper surface and the side surface of the sacrificial gate structure 210.

In the embodiments, the upper etch stop film 185B may be formed on the lower surface of the upper source/drain pattern 150B, as well as on the upper surface and the partial region of the side surface of the upper source/drain pattern 150B. As described with reference to FIGS. 32 and 33, this may be due to a process characteristic in which a partial region of the first interlayer insulation layer 171 formed on the lower source/drain pattern 150A is removed again by an etch back process. On the cross-sectional view of FIG. 37 cut along the second direction D2 and the third direction D3, the upper etch stop film 185B may be conformally formed on the upper surface, the lower surface, and the entire side surface of the upper source/drain pattern 150B. The upper etch stop film 185B may also be formed on the upper surface of the lower etch stop film 185A covering or overlapping the upper surface of the first lower source/drain pattern 150A and on the upper surface of the interlayer insulation layer 171.

Referring to FIG. 36, the upper etch stop film 185B may also be formed on the side surface of the intermediate insulation pattern 181. Specifically, the upper etch stop film 185B may be conformally formed on the side surface of the lower etch stop film 185A covering the side surface of the intermediate insulation pattern 181.

As illustrated in FIG. 38, a second interlayer insulation layer 173 may be formed on the upper source/drain pattern 150B. Although not clearly illustrated, in the embodiments, the second interlayer insulation layer 173 may also be formed on the side surface of the upper source/drain pattern 150B (see FIGS. 4 and 6). In the embodiments, the second interlayer insulation layer 173 may not be filled in at least a partial region between the upper surface of the lower source/drain pattern 150A and the lower surface of the upper source/drain pattern 150B. Accordingly, an air gap AG may be formed between the upper surface of the lower source/drain pattern 150A and the lower surface of the upper source/drain pattern 150B, or between the side surfaces of two intermediate insulation patterns 181 that face each other along the first direction D1. Subsequently, the sacrificial gate structure 210 may be removed, and the upper sacrificial layer 120C and the lower sacrificial layer 120A may be removed to form gate trenches 130t between a plurality of channel patterns 140. In some embodiments, the process of removing the sacrificial gate structure 210, the upper sacrificial layer 120C, and the lower sacrificial layer 120A may be performed simultaneously.

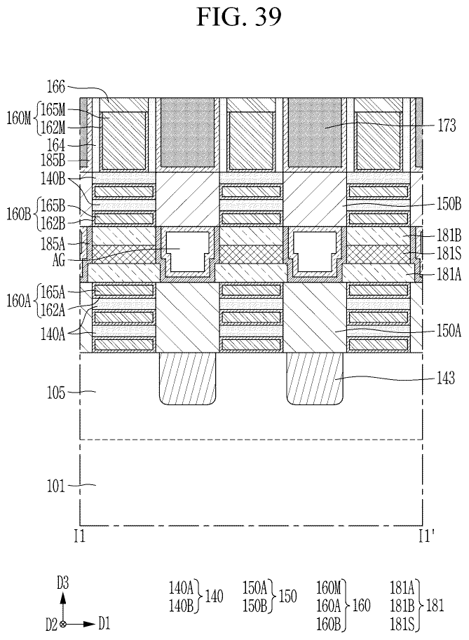

As illustrated in FIG. 39, sub-gate insulation films 162A and 162B and a main gate insulation film 162M may be formed in the gate trench 130t, sub-gate electrodes 165A and 165B and a main gate electrode 165M may be formed, and a capping layer 166 may be formed on the main gate electrode 165M.

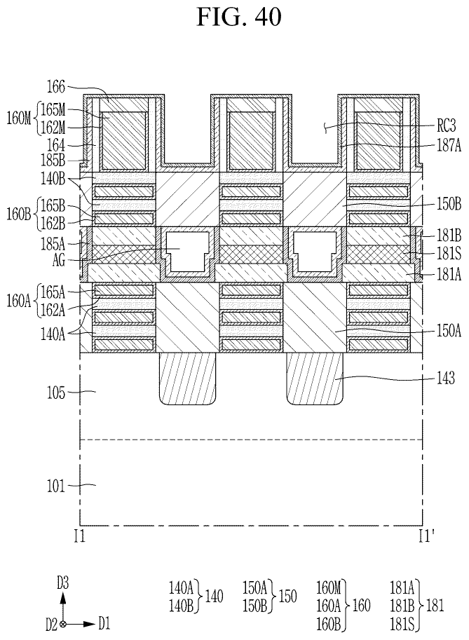

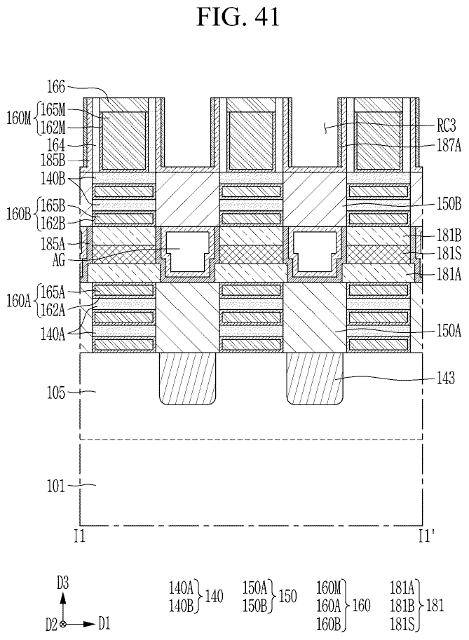

Next, a first protection pattern 187A may be formed on the side surface of the gate spacer 164. First, as illustrated in FIG. 40, the first protection pattern 187A may be formed to entirely cover or overlap the upper surface of the capping layer 166, the upper surface and the side surface of the gate spacer 164. Subsequently, partial regions of the first protection pattern 187A positioned on the upper surface of the capping layer 166, the upper surface of the gate spacer 164, and the upper surface of the upper source/drain pattern 150B may be removed by an anisotropic etching process, so that the first protection pattern 187A may be formed on the side surface of the gate spacer 164, as illustrated in FIG. 41. In the embodiments, the first protection pattern 187A may include a high-k dielectric material. For example, the first protection pattern 187A may include at least one of Al₂O₃, CaF, Y₂O₃, ZrO₂, HfO₂, and/or MgO.

Next, a connection electrode 199 for connecting the lower source/drain pattern 150A and the upper source/drain pattern 150B may be formed by a photo and etching process.

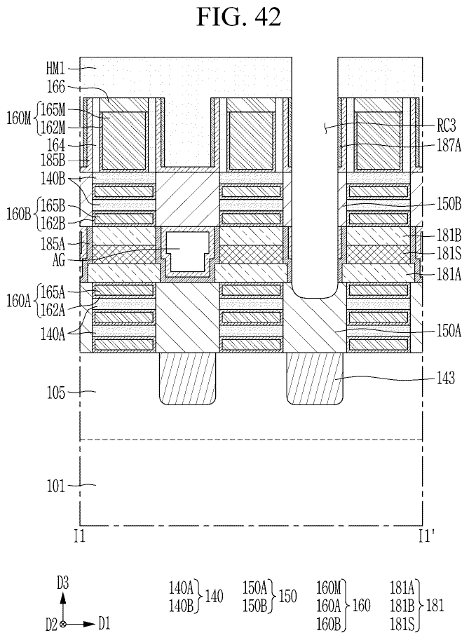

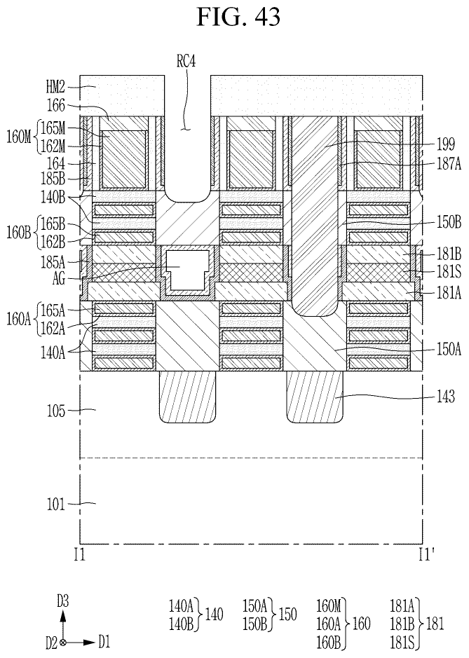

First, as illustrated in FIG. 42, a first hardmask HM1 covering or overlapping the gate structure 160 and the source/drain pattern 150 may be formed. Thereafter, the first hardmask HM1 may be patterned to expose the upper surface of the upper source/drain pattern 150B on which the connection electrode 199 is to be formed. Subsequently, a third recess RC3 may be formed by penetrating or extending into the upper source/drain pattern 150B in the third direction D3 and recessing the lower source/drain pattern 150A to a predetermined depth by the anisotropic etching process. In the embodiments, the first protection pattern 187A may have a low etch selectivity with respect to the etching material. Accordingly, in the process of forming the third recess RC3, the gate spacer 164 and the upper etch stop film 185B positioned on the side surface of the gate spacer 164 may be protected without being damaged by the etching material. Subsequently, the connection electrode 199 may be formed by filling the third recess RC3 with a conductive material (see FIG. 43).

Next, as illustrated in FIG. 43, a second hardmask HM2 covering or overlapping the gate structure 160 and the source/drain pattern 150 may be formed. Thereafter, the second hardmask HM2 may be patterned to expose the upper surface of the upper source/drain pattern 150B on which the upper contact electrode 191 is to be formed. Subsequently, a fourth recess RC4 may be formed to recess the lower source/drain pattern 150A to a predetermined depth by an anisotropic etching process. In the process of forming the fourth recess RC4, the gate spacer 164 and the upper etch stop film 185B positioned on the side surfaces of the gate spacer 164 may be protected without being damaged by the etching material.

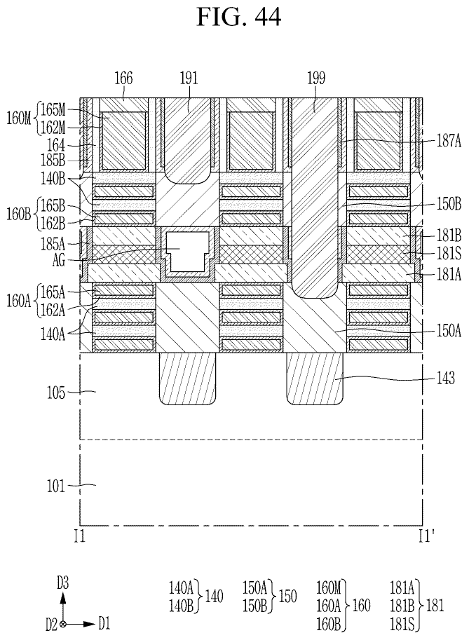

Then, as illustrated in FIG. 44, the fourth recess RC4 may be filled with a conductive material to form the upper contact electrode 191.

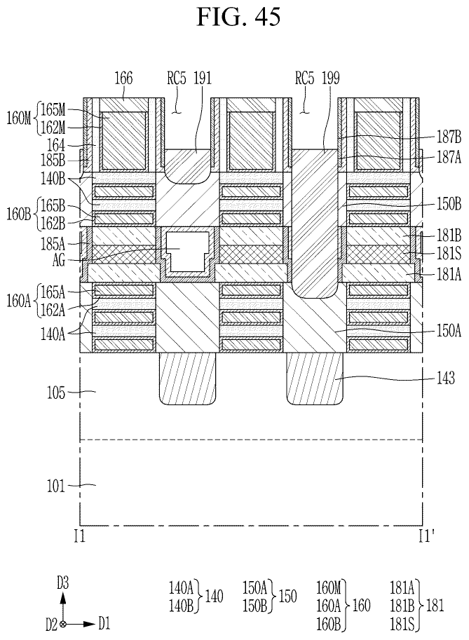

Next, as illustrated in FIG. 45, a partial region of the upper contact electrode 191 and the connection electrode 199 may be re-etched to form the fifth recess RC5 by the etch-back process. In this case, the upper contact electrode 191 and the connection electrode 199 may be etched such that the upper surface is positioned between the upper surface and the lower surface of the main gate structure 160M.

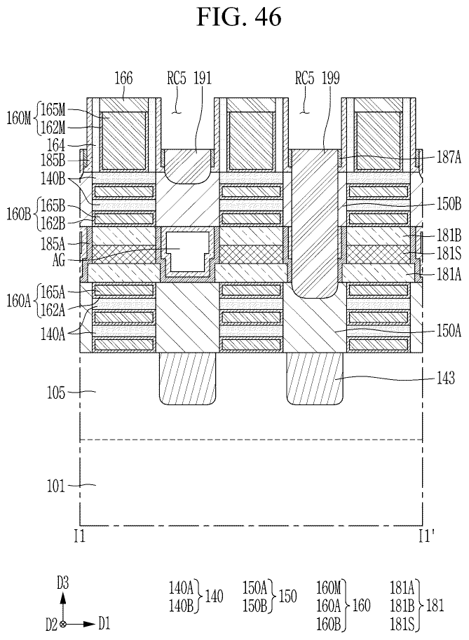

As illustrated in FIG. 46, a partial region of the first protection pattern 187A may be etched. In the embodiments, the first protection pattern 187A may be etched using an etching material having higher etch selectivity with respect to the first protection pattern 187A compared to the upper contact electrode 191 or the connection electrode 199. Accordingly, as illustrated in FIG. 46, a partial region of the first protection pattern 187A, which is positioned at a higher level than the upper surface of the upper contact electrode 191 or the connection electrode 199, may be removed from the entire region of the first protection pattern 187A.

Unlike the illustration in FIG. 46, the first protection pattern 187A may be completely removed. In this case, in the process of etching the upper contact electrode 191 and the connection electrode 199 described with reference to FIG. 45, the upper contact electrode 191 and the connection electrode 199 may be etched such that the upper surfaces thereof are positioned at a lower level than the upper surface of the upper etch stop film 185B positioned on the upper surface of the upper source/drain pattern 150B.

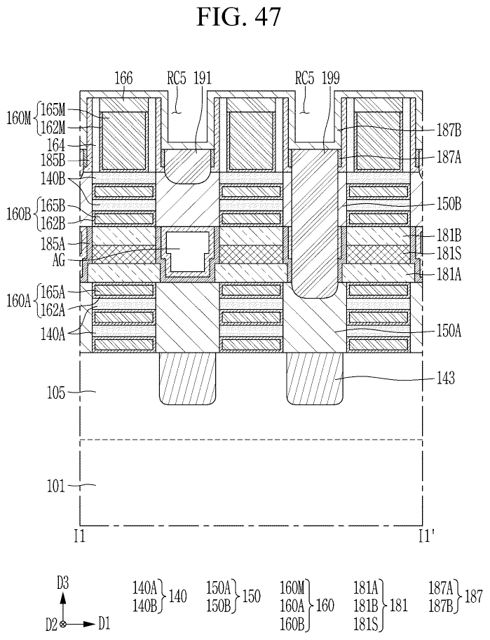

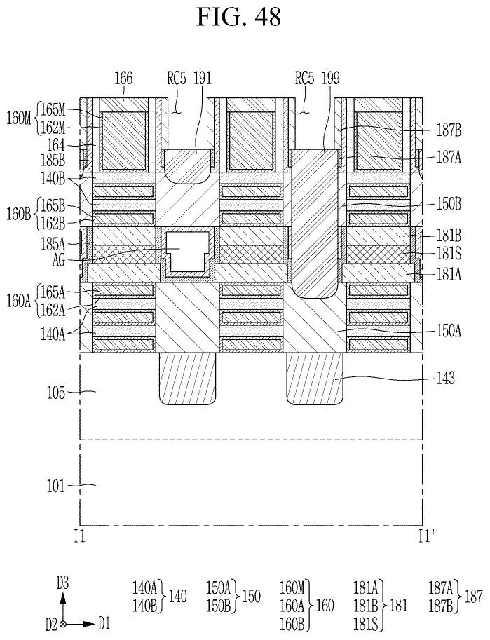

Next, a second protection pattern 187B may be conformally formed on the inner surface of the fifth recess RC5. First, as illustrated in FIG. 47, a second protection pattern 187B may be formed to entirely cover or overlap the upper surface of the capping layer 166, the upper surface and the side surface of the gate spacer 164. Subsequently, by an anisotropic etching process, partial regions of the second protection pattern 187B positioned on the upper surface of the capping layer 166, the upper surface of the gate spacer 164, the upper surface of the upper contact electrode 191, and the upper surface of the connection electrode 199 may be removed to form the second protection pattern 187B on the inner surface of the fifth recess RC5, as illustrated in FIG. 48. In the embodiments, the second protection pattern 187B may include a high dielectric material. For example, the second protection pattern 187B may include at least one of SiOCN, SiCN, SiBCN, and/or BN.

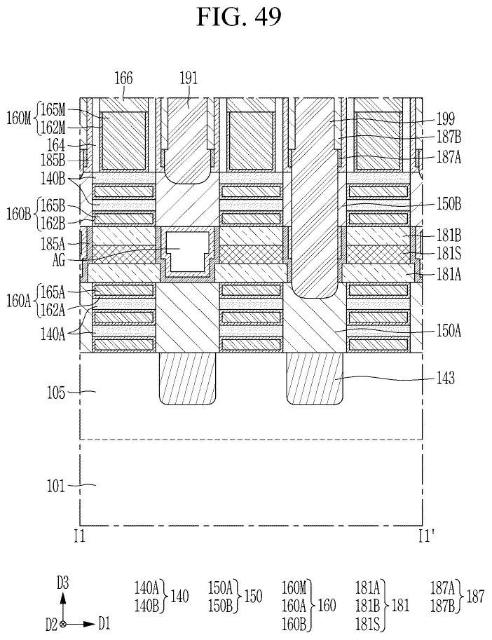

As illustrated in FIG. 49, the fifth recess RC5 may be filled with a conductive material. In the embodiments, the upper surfaces of the upper contact electrode 191 and the connection electrode 199 may be positioned on the same plane as the upper surfaces of the capping layer 166 and the gate spacer 164.

According to the embodiments, at least a portion of the first protection pattern 187A including the high-k dielectric material may be removed, and the second protection pattern 187B including the low-k dielectric material may be formed thereon. Accordingly, parasitic capacitance around the connection electrode 199 or the upper contact electrode 191 may be reduced, and thus electrical characteristics of the semiconductor device according to the embodiments may be improved.

Although some embodiments of the present disclosure has been described in detail, the scope of the present disclosure is not limited by the embodiments. Various changes and modifications using the basic concept of the present disclosure defined in the accompanying claims by those skilled in the art shall be construed to belong to the scope of the present disclosure.

What is claimed is:

1. A semiconductor device comprising:
a substrate;
a lower channel pattern on a surface of the substrate;
an upper channel pattern on the lower channel pattern;
a gate structure extending around the lower channel pattern and the upper channel pattern;
lower source/drain patterns on sidewalls of the lower channel pattern;
upper source/drain patterns on sidewalls of the upper channel pattern;
a connection electrode electrically connecting a first upper source/drain pattern of the upper source/drain patterns to a first lower source/drain pattern of the lower source/drain patterns; and
a protection pattern between the gate structure and the connection electrode,
wherein the protection pattern includes a first protection pattern and a second protection pattern on the first protection pattern, and
wherein the second protection pattern comprises a second insulating material having a second dielectric constant that is less than a first dielectric constant of a first insulating material of the first protection pattern.

2. The semiconductor device of claim 1, wherein the first upper source/drain pattern and the first lower source/drain pattern are spaced apart from each other, and
wherein an air gap is between the first upper source/drain pattern and the first lower source/drain pattern.

3. The semiconductor device of claim 2, further comprising:
an intermediate insulation pattern between the upper channel pattern and the lower channel pattern,
wherein the intermediate insulation pattern is on a side of the connection electrode, and
wherein the air gap is between the intermediate insulation pattern and the connection electrode.

4. The semiconductor device of claim 2, further comprising:
a gate spacer on a side surface of the gate structure; and
an upper etch stop film on at least a portion of the gate spacer and on the first upper source/drain pattern,
wherein the upper etch stop film is between the first upper source/drain pattern and the air gap.

5. The semiconductor device of claim 4, further comprising:
a lower etch stop film on a portion of the first lower source/drain pattern,
wherein the upper etch stop film is between the lower etch stop film and the air gap.

6. The semiconductor device of claim 1, further comprising:
a main gate structure on the upper channel pattern,
wherein the first protection pattern is between a lower side of the main gate structure and the connection electrode, and the second protection pattern is between an upper side of the main gate structure and the connection electrode.

7. The semiconductor device of claim 1, wherein the first protection pattern and the second protection pattern extend in a first direction perpendicular to the surface of the substrate, and
wherein a width of the second protection pattern in a second direction parallel to the surface of the substrate and perpendicular to the first direction is greater than or equal to a width of the first protection pattern in the second direction.

8. The semiconductor device of claim 7, wherein a ratio of a length of the second protection pattern extending in the first direction to a length of the first protection pattern extending in the first direction is greater than or equal to 1 and less than or equal to 5.

9. The semiconductor device of claim 7, wherein the connection electrode extends into the first upper source/drain pattern in the first direction, and an end portion of the connection electrode contacts the first lower source/drain pattern.

10. The semiconductor device of claim 7, wherein the connection electrode includes a first portion overlapping the first protection pattern in the second direction, and a second portion overlapping the second protection pattern in the second direction, and
wherein a width of the first portion in the second direction is greater than a width of the second portion in the second direction.

11. The semiconductor device of claim 1, further comprising:
an upper contact electrode on a second upper source/drain pattern of the upper source/drain patterns that is adjacent to the first upper source/drain pattern and is electrically connected to the connection electrode through ones of the upper source/drain patterns,
wherein the protection pattern is between the upper contact electrode and the gate structure.

12. The semiconductor device of claim 1, wherein the first upper source/drain pattern and the first lower source/drain pattern are spaced apart from each other, and
wherein the semiconductor device further includes an interlayer insulation layer between the first upper source/drain pattern and the first lower source/drain pattern, and
wherein the interlayer insulation layer includes SiO₂, or includes an insulating material having a dielectric constant that is less than that of SiO₂.

13. The semiconductor device of claim 1, wherein the first protection pattern includes at least one of Al₂O₃, CaF, Y₂O₃, ZrO₂, HfO₂, or MgO.

14. The semiconductor device of claim 1, wherein the second protection pattern includes the second insulating material with the second dielectric constant that is less than that of SiO₂.

15. The semiconductor device of claim 1, wherein the second protection pattern includes at least one of SiOCN, SiCN, SiBCN, or BN.

16. A semiconductor device comprising:
a substrate;
a lower channel pattern on a surface of the substrate;
an upper channel pattern on the lower channel pattern;
a gate structure extending around the lower channel pattern and the upper channel pattern;
lower source/drain patterns on sidewalls of the lower channel pattern;
upper source/drain patterns on sidewalls of the upper channel pattern;
a connection electrode electrically connecting a first upper source/drain pattern of the upper source/drain patterns to a first lower source/drain pattern of the lower source/drain patterns; and
a protection pattern between a first portion of a side surface of the gate structure and the connection electrode,
wherein a first air gap is between the connection electrode and a second portion of the side surface of the gate structure.

17. The semiconductor device of claim 16, wherein the first upper source/drain pattern and the first lower source/drain pattern are spaced apart from each other, and
wherein a second air gap is between the first upper source/drain pattern and the first lower source/drain pattern.

18. The semiconductor device of claim 16, further comprising:
a gate spacer on the side surface of the gate structure; and
an upper etch stop film on at least a portion of the gate spacer and on the first upper source/drain pattern,
wherein the upper etch stop film is between the first upper source/drain pattern and the first air gap.

19. The semiconductor device of claim 16, further comprising:
an upper contact electrode on a second upper source/drain pattern of the upper source/drain patterns that is adjacent to the first upper source/drain pattern and is electrically connected to the connection electrode through ones of the upper source/drain patterns,
wherein the protection pattern is between the upper contact electrode and the gate structure.

20. A semiconductor device comprising:
a substrate;
a lower channel pattern on a surface of the substrate;
an upper channel pattern on the lower channel pattern;
an intermediate insulation pattern between the upper channel pattern and the lower channel pattern;
a gate structure extending around the lower channel pattern and the upper channel pattern;
a gate spacer on a portion of a side surface of the gate structure;
lower source/drain patterns on sidewalls of the lower channel pattern;
upper source/drain patterns on sidewalls of the upper channel pattern;
a connection electrode extending into a first upper source/drain pattern of the upper source/drain patterns in a first direction perpendicular to the surface of the substrate and having an end portion electrically connected to a first lower source/drain pattern of the lower source/drain patterns;
an upper contact electrode on an upper surface of a second upper source/drain pattern of the upper source/drain patterns that is adjacent to the first upper source/drain pattern, wherein the connection electrode extends into the first upper source/drain pattern; and
a protection pattern between the gate spacer and the connection electrode and between the gate spacer and the upper contact electrode,
wherein the protection pattern includes a first protection pattern and a second protection pattern on the first protection pattern and including an insulating material having a dielectric constant that is less than a dielectric constant of the first protection pattern.
